(19) United States
(12) Patent Application Publication
(10) Pub. No.: US 2026/0134901 A1
(43) Pub. Date: May 14, 2026

(54) SEMICONDUCTOR DEVICE AND WRITING METHOD

(71) Applicant: Renesas Electronics Corporation, Tokyo (JP)

(72) Inventors: Yohei SATO, Tokyo (JP); Shota OKAYAMA, Tokyo (JP); Yuichiro YAMAGUCHI, Tokyo (JP); Koichi TAKEDA, Tokyo (JP); Hirofumi HEBISHIMA, Tokyo (JP); Takashi KAWANO, Tokyo (JP)

(21) Appl. No.: 19/178,029

(22) Filed: Apr. 14, 2025

Related U.S. Application Data
(60) Provisional application No. 63/635,980, filed on Apr. 18, 2024.

(30) Foreign Application Priority Data
Nov. 15, 2024 (JP) 2024-199720

(51) Int. Cl. G11C 11/16

(52) U.S. Cl. CPC G11C 11/1675; G11C 11/1693; G11C 11/1697

(57) ABSTRACT

A semiconductor device includes a plurality of data lines, a plurality of memory cells connected to the plurality of data lines, and a plurality of FF circuits corresponding to the plurality of data lines. The semiconductor device further includes a memory array circuit including an input circuit that is supplied with a high voltage during writing and writes data to the memory cell connected to the corresponding data line according to data held in the FF circuit. The semiconductor device further includes a memory controller that supplies a data string having a number of pieces of data corresponding to a number of FF circuits to the input circuit and causes the FF circuit to hold the data string. The memory controller includes a pop counter circuit that counts a number of pieces of inverted data included in the data string, and the memory controller divides the FF circuit into a plurality of regions based on counting by the pop counter circuit so that the number of FF circuits that store inverted data is equal to or less than a predetermined number. The input circuit is controlled to select the plurality of regions at different timings and simultaneously write data held in the FF circuits arranged in the selected regions.

### CROSS-REFERENCE TO RELATED APPLICATIONS

The disclosures of U.S. Patent Provisional Application No. 63/635,980 filed on Apr. 18, 2024 and Japanese Patent Application No. 2024-199720 filed on Nov. 15, 2024 including the specification, drawings and abstract are incorporated herein by reference in their entirety.

### BACKGROUND

The present invention relates to a semiconductor device and a writing method, and relates to, for example, a semiconductor device including a plurality of variable-resistance memory cells and a method of writing data to the variable-resistance memory cells.

Variable-resistance memory cells (hereinafter also simply referred to as memory cells) indicate memory cells including storage elements of which resistance values are changed according to stored information (data). As electrically rewritable nonvolatile storage devices (hereinafter also simply referred to as nonvolatile storage devices) configured by such memory cells, for example, there are magnetoresistive memories (magnetoresistive random access memories, hereinafter also referred to as MRAMs).

The MRAM includes, for example, a memory array circuit and a memory controller that reads and writes data from and to the memory array circuit in response to an instruction from a processor. Here, the memory array circuit includes, for example, a plurality of memory blocks in which a plurality of memory cells are arranged in a matrix form, an input/output circuit corresponding to the plurality of memory blocks, and a booster circuit that generates a high voltage. For example, when data is written, the data is supplied from the memory controller to the input/output circuit. The input/output circuit supplies the high voltage generated by the booster circuit to the plurality of memory cells according to the supplied data, and writes the data to the plurality of memory cells.

There are disclosed techniques listed below.

[Non-Patent Document 1] “7.2 4 Mb STT-MRAM-Based Cache with Memory-Access-Aware Power Optimization and Write-Verify-Write/Read-Modify-Write Scheme”, ISSCC 2016/SESSION 7/NONVOLATILE MEMORY SOLUTIONS/ 7.2, 2016 IEEE International Solid-State Circuit Conference.

[Non-Patent Document 2] “13.3 A 7 Mb STT-MRAM in 22FFL FinFET Technology with 4 ns Read sensing Time at 0.9V Using Write-Verify-Write Scheme and Offset-Cancellation Sensing Technique”, ISSCC 2019/SESSION 13/NON-VOLATILE MEMORIES/13.3, 2019 IEEE International Solid-State Circuit Conference.

The MRAM is described in, for example, Non-Patent Document 1 and Non-Patent Document 2. Non-Patent Document 1 and Non-Patent Document 2 show that in the MRAM, reading is executed before data is written, and it is determined whether it is necessary to rewrite data. Also, Non-Patent Document 1 shows that a write signal is masked when it is determined that it is necessary to rewrite data, and Non-Patent Document 2 shows that a voltage to be applied to a memory cell is gradually increased when data is rewritten.

### SUMMARY

When a state (resistance value) of the memory cell is changed by writing, that is, when rewriting is executed, it is necessary to supply the high voltage generated by the booster circuit to the memory cell. To suppress an increase in an occupied area, the booster circuit has a limited current supply capability. Due to limitation of the current supply capability, the number of memory cells that can be rewritten simultaneously is limited. Therefore, when a large amount of memory cells are rewritten, it is necessary to execute write operations in a plurality of cycles, and thus there is a problem that a writing time becomes long.

Non-Patent Document 1 and Non-Patent Document 2 show that it is determined whether it is necessary to execute rewriting, but do not show a current supply capability of a booster circuit.

An outline of representative embodiments disclosed in the present application will be described briefly as follows.

That is, a semiconductor device according to an embodiment includes: a memory array circuit configured to include a plurality of data lines, a plurality of memory cells connected to the plurality of data lines, and an input circuit that includes a plurality of storage circuits, is supplied with a high voltage during writing, and writes data to the memory cells according to data held in the storage circuits; and a memory controller configured to supply a data string having a number of pieces of data corresponding to a number of storage circuits to the input circuit and cause the plurality of storage circuits to hold the data string. Here, inverted data that changes a state of the memory cell by writing to the memory cell and non-inverted data that does not change the state of the memory cell are mixed in the data string. The memory controller includes a counter circuit that counts a number of pieces of the inverted data included in the data string, and controls the input circuit to divide the plurality of storage circuits that store the data string into a plurality of regions so that the number of storage circuits that store inverted data is equal to or less than a predetermined number based on counting by the counter circuit, select the plurality of regions at different timings, and simultaneously write data held in the storage circuits arranged in the selected regions.

Other problems and novel features will become apparent from the description of the present specification and the appended drawings.

According to one embodiment, it is possible to provide a semiconductor device capable of suppressing an increase in a writing time.

### BRIEF DESCRIPTION OF THE DRAWINGS

FIG. 1 is a block diagram illustrating a configuration of a semiconductor device according to a first embodiment.

FIGS. 2A and 2B are diagrams illustrating generation of a P-write data string and an AP-write data string by a memory controller according to the first embodiment.

FIG. 3 is a diagram illustrating a pop counter circuit according to the first embodiment.

FIG. 4 is a diagram illustrating a determination circuit according to the first embodiment.

FIG. 5 is a diagram illustrating the determination circuit according to the first embodiment.

FIG. 6 is a diagram illustrating the determination circuit according to the first embodiment.

FIG. 7 is a diagram illustrating data output from a bit calculation circuit to a lookup table according to the first embodiment.

FIG. 8 is a diagram illustrating data output from the bit calculation circuit to the lookup table according to the first embodiment.

FIGS. 9A and 9B are diagrams illustrating a write operation according to the first embodiment.

FIG. 10 is a flowchart illustrating an operation of the semiconductor device according to the first embodiment.

FIG. 11 is a circuit diagram illustrating a configuration example of a memory array circuit according to the first embodiment.

FIG. 12 is a timing chart illustrating an operation of the memory array circuit according to the first embodiment.

FIG. 13 is a diagram illustrating a semiconductor device according to a modification of the first embodiment.

FIG. 14 is a diagram illustrating the semiconductor device according to the modification of the first embodiment.

FIGS. 15A and 15B are diagrams illustrating a semiconductor device according to a second embodiment.

FIG. 16 is a diagram illustrating a semiconductor device according to a modification of the second embodiment.

FIG. 17 is a block diagram illustrating a configuration of the semiconductor device according to the modification of the second embodiment.

FIG. 18 is a diagram illustrating a lookup table according to the modification of the second embodiment.

FIG. 19 is a block diagram illustrating a configuration of a semiconductor device according to a third embodiment.

FIG. 20 is a diagram illustrating the semiconductor device according to the third embodiment.

FIGS. 21A and 21B are diagrams illustrating a write operation according to the third embodiment.

FIG. 22 is a timing chart illustrating the write operation according to the third embodiment.

FIGS. 23A and 23B are diagrams illustrating a configuration example of an MRAM.

FIGS. 24A to 24C are diagrams illustrating a configuration of an MRAM examined by the present inventors.

### DETAILED DESCRIPTION

Hereinafter, embodiments of the present invention will be described with reference to the drawings. The disclosure is merely exemplary, and appropriate modifications that can be easily conceived by those skilled in the art while maintaining the gist of the invention are naturally included in the scope of the present invention.

In the present specification and the drawings, elements similar to those previously described with respect to aforementioned drawings are denoted by the same reference signs, and detailed description thereof may be appropriately omitted.

### Comparative Example

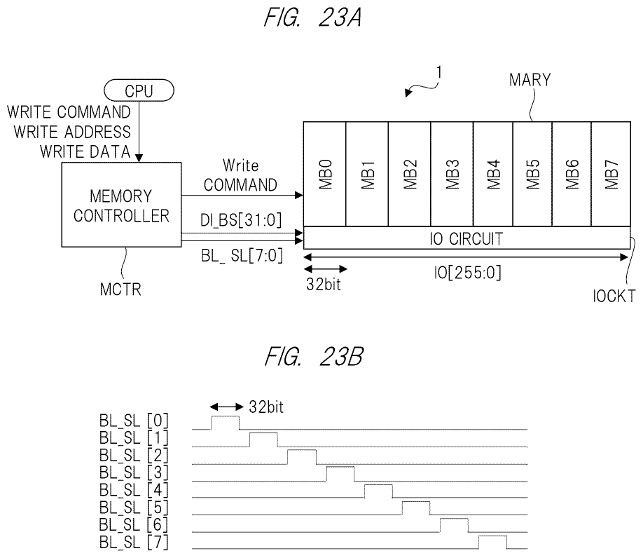

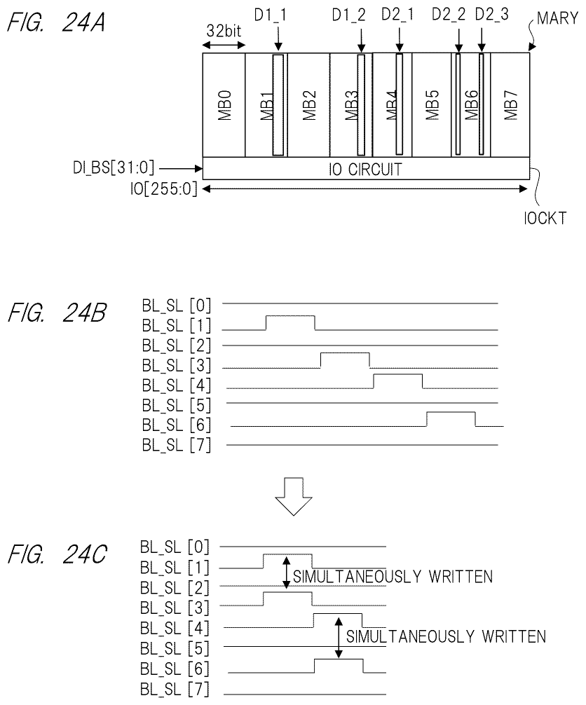

To suppress an increase in a writing time, the present inventors have examined the configuration of an MRAM based on Non-Patent Document 1, Non-Patent Document 2, and the like. To facilitate understanding of a semiconductor device according to an embodiment, a configuration example of an MRAM and a configuration of an examined MRAM will first be described. FIGS. 23A and 23B are diagrams illustrating a configuration example of the MRAM. Here, FIG. 23A is a block diagram illustrating a configuration example of the MRAM, and FIG. 23B is a timing diagram illustrating timings during writing of the MRAM illustrated in FIG. 23A. FIGS. 24A to 24C are diagrams illustrating a configuration of the MRAM examined by the present inventors (hereinafter also referred to as a comparative example). Here, FIG. 24A is a block diagram illustrating a configuration of the comparative example, and FIG. 24B is a timing diagram illustrating a write timing according to the comparative example. FIG. 24C is a timing chart illustrating the outline of an embodiment.

### One Configuration Example of MRAM

In FIG. 23A, a reference sign 1 denotes a semiconductor device. The semiconductor device 1 includes a processor CPU, a memory controller MCTR, and a memory array circuit MARY. The memory array circuit MARY illustrated in FIGS. 23A and 23B includes eight memory blocks MB0 to MB7 and an input/output circuit IOCKT corresponding to the memory blocks MB0 to MB7.

Since the memory blocks MB0 to MB7 have similar configurations, the memory block MB0 will be described as an example. In the memory block MB0, writing and reading can be executed simultaneously with a predetermined bit width (32 bits in FIG. 23A). In a write operation, 32-bit data is supplied from the memory controller MCTR to the input/output circuit IOCKT via an input data bus DI_BS[31:0]. Block select signals BL_SL[7:0] are also supplied from the memory controller MCTR to the input/output circuit IOCKT. The block select signals BL_SL[7:0] correspond one-to-one to the memory blocks MB0 to MB7. For example, the block select signal BL_SL[0] corresponds to the memory block MB0, and the block select signal BL_SL[7] corresponds to the memory block MB7.

During the write operation, for example, when the memory controller MCTR sets the block select signal BL_SL[0] to a selection level (high level), the memory block MB0 corresponding to the block select signal BL_SL[0] is selected, and in the input/output circuit IOCKT, the 32-bit data in the input data bus DI_BS[31:0] is supplied to the memory block MB0 via an input/output circuit unit (hereinafter also referred to as a block input/output circuit) corresponding to the memory block MB0 and is written substantially simultaneously to 32 memory cells in the memory block MB0.

Since the memory blocks MB1 to MB7 are similar to the memory block MB0, the memory controller MCTR can supply and write 32 bits×8=256-bit data (data string) IO[255:0] to the memory array circuit MARY. The data string IO[255:0] to be written is supplied as write data from the processor CPU operating according to programs to the memory controller MCTR. The processor CPU supplies an address to which the data string IO[255:0] is to be written and a write command to the memory controller MCTR. In response to the write command, the memory controller MCTR supplies the write command to the memory array circuit MARY and supplies a write address (not illustrated) to the memory array circuit MARY. Accordingly, in the memory array circuit MARY, the data string IO[255:0] is written to the memory cells (32×8) designated with the write address.

In the present specification, data of a plurality of bits m+1 (data string) is represented by [m:0]. For example, the data string IO[255:0] indicates that 256 bits from the least significant bit data IO[0] to the most significant bit data IO[255] are included. Data at a predetermined location i in the data string IO is represented by IO[i], and a data string in a predetermined range (for example, bits 0 to i) is represented by IO[i:0].

As illustrated in FIG. 23B, the memory controller MCTR can write the data string IO[255:0] to the memory blocks MB0 to MB7 by changing the block select signals BL_SL[0] to BL_SL[7] to the selection level in this order.

Although not illustrated in FIG. 23A, the memory array circuit MARY includes a booster circuit, in which the booster circuit executes a boosting operation to generate a high voltage in response to a change in the block select signals BL_SL[0] to BL_SL[7] to the selection level.

As described in the section of [SUMMARY], when a resistance value of a memory cell is changed, that is, when the memory cell is rewritten, it is necessary to supply a high voltage to the memory cell. To suppress an increase in the occupied area, the booster circuit has a limited current supply capability, and the number of memory cells that can be rewritten simultaneously is limited to a predetermined number. In the example illustrated in FIGS. 23A and 23B, the predetermined number is 32. Therefore, to write the 256-bit data string IO[255:0] to the memory array circuit MARY, the write operation is executed in eight cycles as illustrated in FIG. 23B, and a writing time becomes long.

### Configuration of Comparative Example

The present inventors have considered an MRAM capable of suppressing an increase in a writing time by changing the memory array circuit MARY and the memory controller MCTR in FIGS. 23A and 23B based on Non-Patent Document 1, Non-Patent Document 2, and the like as a comparative example.

FIG. 24A illustrates a configuration of a comparative example examined by the present inventors before the present invention. FIG. 24A illustrates only the memory array circuit MARY and the input/output circuit IOCKT illustrated in FIG. 23A. In FIG. 24A, D1_1, D1_2, D2_1, D2_2, and D2_3 indicate regions in which data is to be rewritten. That is, in the data string IO[255:0] to be written, regions in which data is to be rewritten are the regions D1_1, D1_2, D2_1, D2_2, and D2_3, and other regions are regions in which data is not to be rewritten.

Non-Patent Document 1 and Non-Patent Document 2 show that reading is executed before data is written and it is determined whether it is necessary to rewrite data. Based on the technique, in the comparative example of FIGS. 24A to 24C, before the data string IO[255:0] is written, data is read from the memory blocks MB0 to MB7, and memory blocks in which it is necessary to rewrite data are determined. In the example illustrated in FIG. 24A, since the memory blocks MB1, MB3, MB4, and MB6 include the regions D1_1, D1_2, D2_1, and D2_2, and D2_3 in which data is to be rewritten, the memory blocks are determined as memory blocks in which it is necessary to rewrite data. In the comparative example, only the block select signals BL_SL[1], BL_SL[3], BL_SL[4], and BL_SL[6] for selecting the memory blocks MB1, MB3, MB4, and MB6 determined to be necessary to rewrite data are sequentially set to the selection level as illustrated in FIG. 24B. Accordingly, the data string IO[255:0] can be written by executing the write operation in only four cycles instead of eight cycles, and thus the writing time can be suppressed.

However, in the comparative example, a memory block is a unit of a write region, and for example, even when a total number of memory cells to be rewritten included in the regions D1_1 and D1_2 in two memory blocks MB1 and MB3 is equal to or less than a predetermined number (32), two cycles of the write operation corresponding to the two memory blocks MB1 and MB3 are required, and thus there is a problem that a writing time is still long.

### Outline of Embodiments

In embodiments to be described below, a memory block is not a unit of a write region, and the write region is specified as a region in which a number of memory cells to be substantially simultaneously rewritten is equal to or less than a predetermined number (32). For example, when the total number of memory cells to be rewritten included in the regions D1_1 and D1_2 is equal to or less than the predetermined number and the total number of memory cells to be rewritten included in the regions D2_1, D2_2, and D2_3 is also equal to or less than the predetermined number, as illustrated in FIG. 24C, the block select signals BL_SL[1] and BL_SL[3] are simultaneously set to the selection level, and the block select signals BL_SL[4] and BL_SL[6] are simultaneously set to the selection level. Accordingly, as illustrated in FIG. 24C, the data string IO[255:0] can be written by executing the write operation in only two cycles, and a writing time can be further suppressed.

In FIG. 24A, in reference signs D1_1, D1_2, D2_1, D2_2, and D2_3 indicating regions to be rewritten, numbers 1 and 2 added behind a reference sign D represent a cycle in which writing is executed in FIG. 24C. That is, the regions D1_1 and D1_2 to be rewritten are regions in which writing is executed in a first cycle, and the regions D2_1 to D2_3 to be rewritten are regions in which writing is executed in a second cycle.

### First Embodiment

### Configuration of Semiconductor Device

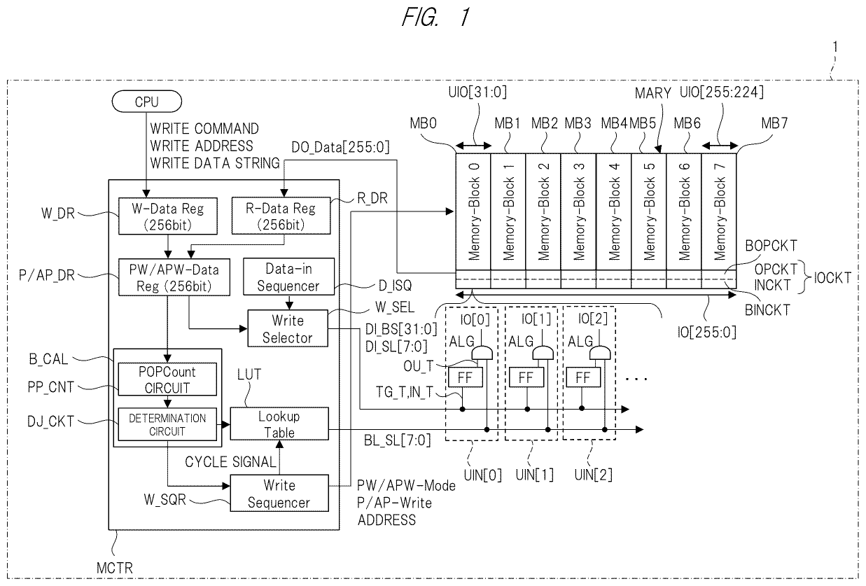

FIG. 1 is a block diagram illustrating a configuration of a semiconductor device according to a first embodiment. In FIG. 1, a reference sign 1 denotes the semiconductor device. Although the semiconductor device 1 includes a plurality of circuit blocks formed on the same semiconductor substrate, only circuit blocks necessary for description are illustrated in FIG. 1 to avoid the drawing becoming complicated.

In FIG. 1, MARY denotes a memory array circuit, MCTR denotes a memory controller, and CPU denotes a processor.

The processor CPU reads a program from a storage device (not illustrated) and executes a predetermined process according to the read program. In the predetermined process, the processor CPU issues a write command and a read command to the memory controller MCTR. When the write command is issued, the processor CPU issues, to the memory controller MCTR, a data string to be written (write data string) to the MRAM and an address indicating an address to be written (write address) to the MRAM.

FIG. 1 illustrates an example in which the MRAM is configured with the memory array circuit MARY and the memory controller MCTR. However, the MRAM may be configured with, for example, only the memory array circuit MARY, and the memory controller MCTR may be a circuit block that controls the MRAM under management of the processor CPU.

### Memory Array Circuit

### Memory Block

In the first embodiment, the memory array circuit MARY includes eight memory blocks MB0 to MB7 and an input/output circuit IOCKT. Since the memory blocks MB0 to MB7 have configurations similar to each other, the memory block MB0 will be described as a representative here.

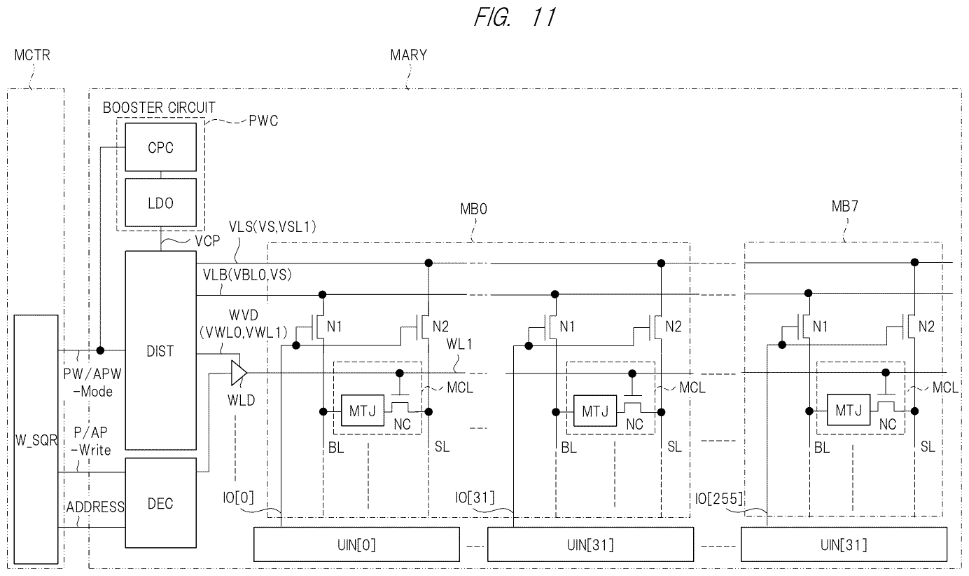

Although not illustrated, the memory block MB0 includes a plurality of memory cells arranged in a matrix form (array form), word lines arranged in each row, and pairs of a bit line and a source line arranged in each column. As to be described below with reference to FIG. 11 and the like, a plurality of memory cells arranged in the same row are connected to the word line arranged in the same row, and a plurality of memory cells arranged in the same column are connected to the pair of the bit line and the source line arranged in the same column. In the write operation, when the selection level is supplied to the word line, the plurality of memory cells connected to the word line is selected, and data is written to the selected memory cells according to voltage in the pair of the bit line and the source line. In the read operation, when the selection level is supplied to the word line, the plurality of memory cells connected to the word line are selected, and voltage of the bit line changes according to data stored in the selected memory cell. In the present specification, the bit line and the source line are also collectively referred to as data lines.

In the memory block MB0, the number of memory cells arranged in one row is 32, and 32 memory cells can be simultaneously selected by supplying the selection level to the word line. Accordingly, during the read operation and the write operation, the memory block MB0 can simultaneously read and write a 32-bit (32-bit width) data string UIO[31:0].

Configurations of the memory blocks MB1 to MB7 are also similar to the configuration of the memory block MB0. Note that the word line is common between the memory blocks MB0 to MB7. In FIG. 1, UIO[255:224] exemplifies a 32-bit data string that can be simultaneously read and written in the memory block MB7. In the other memory blocks MB1 to MB6, a data string can also be simultaneously read and written in a 32-bit data string UIO[m:n]. Here, a location m of a start bit and a location n of an end bit of the 32-bit data string UIO that can be read and written are different for each memory block, and a total of the memory blocks MB0 to MB7 is the 256-bit data string IO[255:0].

### Input/Output Circuit

The input/output circuit IOCKT includes an input circuit INCKT and an output circuit OPCKT. The input circuit INCKT is a circuit used for the write operation and the output circuit OPCKT is a circuit used for the read operation and the write operation.

The input circuit INCKT includes eight block input circuits BINCKT corresponding one-to-one to the memory blocks MB0 to MB7, and the output circuit OPCKT also includes eight block output circuits BOPCKT corresponding one-to-one to the memory blocks MB0 to MB7. In the present specification, a block input circuit BINCKT and a block output circuit BOPCKT corresponding one-to-one to a memory block are collectively referred to as a block input/output circuit corresponding to a memory block.

The block output circuit BOPCKT corresponding to the memory block MB0 includes unit output circuits of a number (32) corresponding to a bit width (32 bits) of the memory block MB0. During the read operation, the 32 unit output circuits output voltages at 32 bit lines in the corresponding memory block MB0 as 32-bit read data to the memory controller MCTR. The same applies to the block output circuits BOPCKT corresponding to the other memory blocks MB1 to MB7, and during the read operation, voltages of bit lines in the corresponding memory block are output as read data to the memory controller MCTR. A 256-bit (32 bits×8=256 bits) data string output from the eight block output circuits BOPCKT corresponding to the memory blocks MB0 to MB7 to the memory controller MCTR in the read operation is denoted as DO_Data[255:0] in FIG. 1.

The eight block input circuits BINCKT corresponding to the memory blocks MB0 to MB7 are connected to the memory controller MCTR by the input data bus DI_BS[31:0], an input data selection line DI_SL[7:0], and the block select signal (block selection line) BL_SL[7:0]. The memory controller MCTR divides the 256-bit data string IO[255:0] to be written to the memory blocks MB0 to MB7 into 32-bit data strings and supplies the divided data strings to 32 input data buses DI_BS[31:0] by time-sharing. The memory controller MCTR supplies, to the input data selection line DI_SL[7:0], an input data select signal for designating a memory block to which the divided 32-bit data is to be supplied among the memory blocks MB0 to MB7.

For example, when the 32-bit data string is supplied to the block input circuit BINCKT corresponding to the memory block MB0, the memory controller MCTR supplies, for example, an input data select signal with a high level (selection level) to the input data selection line DI_SL[0] for designating the memory block MB0, and supplies an input data select signal with a low level (non-selection level) to the input data selection lines DI_SL[1] to DI_SL[7] for designating the remaining memory blocks MB1 to MB7. The input data bus DI_BS[31:0] is common to the eight block input circuits BINCKT corresponding to the memory blocks MB0 to MB7, and by supplying the input data select signal with the high level only to the block input circuit BINCKT corresponding to the memory block MB0, the 32-bit data string in the input data bus DI_BS[31:0] is delivered only to the memory block MB0.

The block input circuits corresponding to the other memory blocks MB1 to MB7 are also similar to the block input circuit corresponding to the memory block MB0. The memory controller MCTR supplies the 32-bit data string corresponding to the memory block MB0 to the input data bus DI_BS[31:0] and supplies the input data line select signal with the high level to the input data selection line DI_SL[0], and then the memory controller MCTR supplies the 32-bit data string corresponding to the memory block MB1 to the input data bus DI_BS[31:0] and supplies the input data line select signal with the high level to the input data selection line DI_SL[1]. Here, the input data line select signal with the low level is supplied to the input data selection lines DI_SL[0] and DI_SL[7:2] other than the input data selection line DI_SL[1]. Accordingly, the 32-bit data string corresponding to the memory block MB1 is delivered only to the block input circuit corresponding to the memory block MB1.

Thereafter, the memory controller MCTR sequentially supplies the 32-bit data strings corresponding to the memory blocks MB2 to MB7 to the input data bus DI_BS[31:0], and supplies the input data line select signal with the high level to the input data selection lines DI_SL[2] to DI_SL[7] in this order. Accordingly, the 256-bit data string IO[255:0] is delivered to the eight block input circuits BINCKT corresponding to the memory blocks MB0 to MB7.

### Unit Input Circuit

The block input circuit BINCKT includes a unit input circuit UIN corresponding to the pair of the bit line and the source line in the corresponding memory block. Since the memory block according to the first embodiment has a width of 32 bits, the block input circuit BINCKT includes 32 unit input circuits. In FIG. 1, three unit input circuits UIN[0] to UIN[2] are exemplified among the 32 unit input circuits included in the block input circuit BINCKT corresponding to the memory block MB0. Since the 32 unit input circuits have similar configurations, the unit input circuit UIN[0] will be described as an example.

The unit input circuit UIN[0] includes a flip-flop circuit (hereinafter also referred to as an FF circuit) FF and an AND circuit (logic circuit) ALG. The FF circuit FF includes a trigger terminal TG_T, an input terminal IN_T, and an output terminal OU_T. The trigger terminal TG_T is connected to the input data selection line DI_SL[0] corresponding to the memory block MB0 among the input data selection lines DI_SL[7:0], and the input terminal IN_T is connected to one input data bus DI_BS[0] among the input data buses DI_BS[31:0]. The AND circuit ALG is a two-input AND circuit, in which one input terminal is connected to the output terminal OU_T of the FF circuit FF and the other input terminal is connected to the block select signal BL_SL[0] corresponding to the memory block MB0 among the block select signals BL_SL[7:0].

When the input data select signal with the selection level (high level) is supplied to the input data selection line DI_SL[0] connected to the trigger terminal TG_T, the FF circuit FF in the unit input circuit UIN[0] delivers and holds data (logic value of 1 or 0) in the input data bus DI_BS[0] connected to the input terminal IN_T. When the selection level (high level) for designating selection of the memory block MB0 is supplied to the block select signal BL_SL[0], the AND circuit ALG supplies the data (1 or 0) held in the FF circuit FF as the input data (1 bit from the data string IO[255:0], hereinafter also referred to as a write enable signal) IO[0] to be written to the corresponding memory block MB0. In the write operation, in the memory block MB0, voltage of the bit line and the source line corresponding to the unit input circuit UIN[0] becomes a value corresponding to the data held in the FF circuit FF, and rewriting or the like is executed.

The other unit input circuits UIN[1] to UIN[31] arranged in the block input circuit BINCKT corresponding to the memory block MB0 are also similar to the unit input circuit UIN[0] except that the input data buses DI_BS[31:0] to which the input terminals IN_T of the unit input circuits are connected are different. For example, the input terminal IN_T of the FF circuit FF is connected to the input data bus DI_BS[1] in the unit input circuit UIN[1], the input terminal IN_T of the FF circuit FF is connected to the input data bus DI_BS[2] in the unit input circuit UIN[2], and the input terminal IN_T of the FF circuit FF is connected to the input data bus DI_BS[31] in the unit input circuit UIN[31] (not illustrated).

Accordingly, when the input data select signal with the selection level is supplied to the input data selection line DI_SL[0], the 32-bit data strings IO[31:0] of the 256-bit data string IO[255:0] supplied from the memory controller MCTR is held in the 32 unit input circuits UIN[0] to UIN[31] in the block input circuit BINCKT corresponding to the memory block MB0.

Similarly to the block input circuit BINCKT corresponding to the memory block MB0, the block input circuits BINCKT corresponding to the memory blocks MB1 to MB7 also include 32 unit input circuits UIN[0] to UIN[31]. A difference between the unit input circuits for the memory block MB0 and the unit input circuits for the other memory blocks MB1 to MB7 is that the input data selection lines connected to the trigger terminals TG_T of the FF circuits FF and the block selection lines connected to the other input terminals of the AND circuits ALG are different. That is, the input data selection lines DI_SL[1] to DI_SL[7] are connected to the trigger terminals TG_T of the FF circuits FF for the memory blocks MB1 to MB7, and the block select signals BL_SL[1] to BL_SL[7] are connected to the other input terminals of the AND circuits ALG.

Accordingly, for example, the memory controller MCTR holds the 256-bit data string IO[255:0] supplied to the input data bus DI_BS[31:0] by time-sharing in 256 (32×8) unit input circuits in the block input circuit BINCKT corresponding to the memory blocks MB0 to MB7 by setting the input data selection line to the selection level in the order of DI_SL[0] to DI_SL[7]. In the write operation, the memory controller MCTR can supply the data string held in advance in the unit input circuit to the corresponding memory block and execute rewriting or the like by changing the block select signals BL_SL[7:0] to the selection level.

### Memory Controller

Next, the memory controller MCTR will be described. The memory controller MCTR executes the read operation and the write operation on the memory array MARY in response to the read command and the write command from the processor CPU. In the present specification, the write operation by the memory controller MCTR will be described. Therefore, in the memory controller MCTR illustrated in FIG. 1, only circuit blocks related to the write operation are mainly illustrated, and circuit blocks related to reading will be mainly omitted.

The memory controller MCTR includes a write data register W_DR, a read data register R_DR, a P/AP-write register P/AP_DR, a data-in sequencer D_ISQ, a write selector W_SEL, a bit calculation circuit B_CAL, a lookup table LUT, and a write sequencer W_SQR. In the write operation, the processor CPU supplies a write command, a write address, and a write data string to the memory controller MCTR. Here, the write data string is a 256-bit data string W_Data[255:0].

When the write command is supplied, the memory controller MCTR according to the first embodiment writes the write data strings W_Data[255:0] from the processor CPU to the write data register W_DR. The memory controller MCTR supplies the write address from the processor CPU as a read address to the memory array circuit MARY, and instructs the memory array circuit MARY to execute the read operation of reading a 256-bit data string held at an address designated with the read address. In response to the instruction, the memory array circuit MARY reads data stored in 256 memory cells designated with the read address, and supplies a read data string DO_Data[255:0] from the output circuit OPCKT to the memory controller MCTR. In the memory controller MCTR, the read data string DO_Data[255:0] is held in the read data register R_DR.

The memory controller MCTR can specify a data portion to be rewritten in the data string by comparing the data strings stored in the read data register R_DR and the write data register W_DR.

The MRAM according to the first embodiment includes a P-write mode and an AP-write mode as write operations. Here, the P-write mode indicates a mode in which the memory cell designated with the write address is rewritten to a logic value of “0”, and the AP-write mode indicates a mode in which the memory cell designated by the write address is rewritten to a logic value of “1”. For example, in the P-write mode, the resistance value of the designated memory cell is changed to a low value, and in the AP-write mode, the resistance value of the designated memory cell is changed to a high value (a value higher than the resistance value set in the P-write mode).

The memory controller MCTR generates a P-write data string PW-Data and an AP-write data string APW-Data by calculating the read data string DO_Data[255:0] stored in the read data register R_DR and the write data strings W_Data[255:0] stored in the write data register W_DR. The memory controller MCTR stores the generated P-write data string PW-Data and AP-write data string APW-Data in the 256-bit P/AP-write register P/AP_DR.

### Generation of P-Write Data String and AP-Write Data String

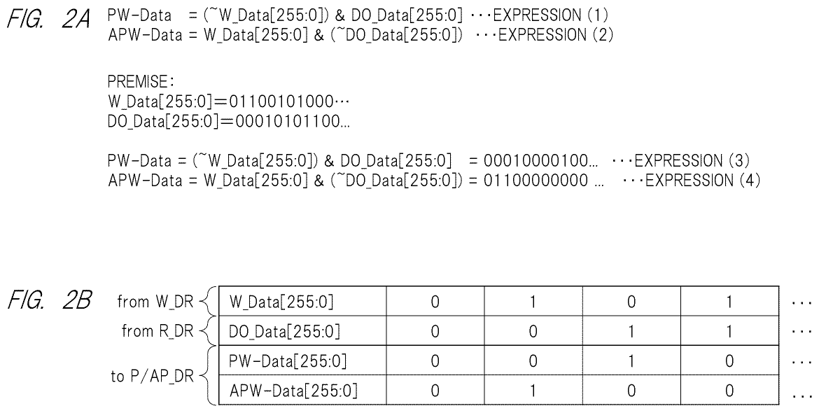

Next, a method of generating the P-write data string PW-Data and the AP-write data string APW-Data will be described with reference to the drawings. FIGS. 2A and 2B are diagrams illustrating generation of the P-write data string and the AP-write data string by the memory controller according to the first embodiment. Here, FIG. 2A illustrates an expression used to generate the P-write data string PW-Data and the AP-write data string APW-Data, and FIG. 2B illustrates an example of the generated P-write data string PW-Data and AP-write data string APW-Data.

The P-write data string PW-Data is generated by Expression (1) illustrated in FIG. 2A, and the AP-write data string APW-Data is generated by Expression (2) illustrated in FIG. 2A. A reference sign “˜” shown in Expressions 1) and (2) indicates bitwise logic inversion, and a reference sign “&” indicates bitwise logic product.

When Expression (1) is described as an example, “(˜W_Data[255:0 ])” indicates that each bit of the 256-bit write data strings W_Data[255:0] is inverted, and Expression (1) indicates that the 256-bit P-write data string PW-Data is generated by executing a logic product calculation between each bit of the write data strings W_Data[255:0] inverted bitwise and each bit of the read data string DO_Data[255:0]. Expression (2) indicates that the 256-bit AP-write data string APW-Data is generated by executing a logic product calculation between each bit of the write data string W_Data[255:0] and each bit of the read data string DO_Data[255:0] inverted bitwise.

Expressions (3) and (4) illustrated in FIG. 2A indicate the P-write data string PW-Data and the AP-write data string APW-Data when the write data string W_Data[255:0] is “01100101000 . . . ” and the read data string DO_Data[255:0] is “00010101100 . . . ” as indicated in premises.

In the table of FIG. 2B, a more specific example is illustrated by clearly indicating particularly lower four bits of the write data string W_Data and the read data string DO_Data. That is, the lower four bits of the write data string W_Data[255:0] are “0101” and the lower four bits of the read data string DO_Data[255:0] are “0011”. Here, the lower four bits of the P-write data string PW-Data are calculated as “0010” according to Expression (1) and the lower four bits of the AP-write data string APW-Data are calculated as “0100” according to Expression (2).

The calculated P-write data string PW-Data and AP-write data string APW-Data are stored in the P/AP-write register P/AP_DR. Although not particularly limited, the memory controller MCTR according to the first embodiment first generates the P-write data string PW-Data and stores the P-write data string PW-Data in the P/AP-write register P/AP_DR. Thereafter, the memory controller MCTR generates the AP-write data string APW-Data and stores the AP-write data string APW-Data in the P/AP-write register P/AP_DR.

As understood from FIG. 2B, when the logic values in the read data string DO_Data[255:0] and the write data string W_Data[255:0] are different at the same bit location, that is, in the write operation of the write data string W_Data[255:0], the logic value is “1” at the bit location at which the rewrite operation is executed and the logic value is “0” at the bit location at which the rewrite operation is not executed in the P-write data string PW-Data or the AP-write data string APW-Data. The P-write data string PW-Data and the AP-write data string APW-Data are data strings in which a logic value of “1” indicating a rewriting target and a logic value of “0” indicating a non-writing target are mixed. Similarly, the write data string W_Data[255:0] supplied from the processor CPU can also be regarded as a data string in which rewriting target bits (inverted data) and non-rewriting target bits (non-inverted data) are mixed.

Returning to FIG. 1, the description will be continued.

### Writing of P-Write Data

The P-write data string PW-Data stored in the P/AP-write register P/AP_DR is supplied to the write selector W_SEL and the bit calculation circuit B_CAL.

The write selector W_SEL is controlled by the data-in sequencer D_ISQ. That is, the data-in sequencer D_ISQ controls the write selector W_SEL to divide the supplied 256-bit data string from the least significant bit to the most significant bit in a unit of 32 bits, and outputs the eight 32-bit data strings obtained by the division to the input data bus DI_BS[31:0] by time-sharing. The data-in sequencer D_ISQ controls the write selector W_SEL to sequentially output the selection level from the input data selection line DI_SL[0] to DI_SL[7] when the 32-bit data strings are output by time-sharing.

Accordingly, the 256-bit P-write data string PW-Data supplied from the P/AP-write register P/AP_DR to the write selector W_SEL is divided every 32 bits, is sequentially supplied from the 32 FF circuits FF in the block input circuit BINCKT corresponding to the memory block MB0 to the 32 FF circuits FF in the block input circuit BINCKT corresponding to the memory block MB7, and is sequentially stored. That is, the 256-bit P-write data string PW-Data as the data string IO[255:0] is delivered to the eight block input circuits BINCKT corresponding to the memory blocks MB0 to MB7.

As will be described in detail below, the bit calculation circuit B_CAL counts the number of logic values “1” indicating the rewriting target included in the supplied P-write data string PW-Data. The bit calculation circuit B_CAL generates block select signals for designating memory blocks to be simultaneously written and a writing order based on the counting result. The block select signals and the writing order generated by the bit calculation circuit B_CAL are supplied to and stored in the lookup table LUT.

The write sequencer W_SQR outputs a cycle signal indicating the writing order to the lookup table LUT in response to an instruction from the bit calculation circuit B_CAL. The write sequencer W_SQR supplies, to the memory array MARY, a mode signal PW/APW-Mode indicating whether the mode is the P-write mode or the AP-write mode, an address based on the write address from the processor CPU, and a write command P/AP-Write instructing writing.

Using the block select signals and the writing order stored in advance, the lookup table LUT selects the block select signal corresponding to the writing order specified with the cycle signal supplied from the write sequencer W_SQR, and sets the selected block select signal to the selection level. Accordingly, as illustrated in FIG. 24C, for example, two or more block select signals are set to the selection level simultaneously, and two or more memory blocks can be simultaneously written across boundaries between memory blocks.

### Writing of AP-Write Data

After the P-write data string PW-Data is written in the memory array MARY, the memory controller MCTR generates the AP-write data string APW-Data by calculating the read data string DO_Data[255:0] stored in the read data register R_DR and the write data string W_Data[255:0] stored in the write data register W_DR, and stores the AP-write data string APW-Data in the P/AP-write register P/AP_DR. Similarly to the P-write data string P-Data, the 256-bit AP-write data string APW-Data stored in the P/AP-write register P/AP_DR is supplied to and stored in the block input circuit BINCKT corresponding to the memory blocks MB0 to MB7 in a unit of 32 bits by the data-in sequencer D_ISQ and the write selector W_SEL. In the 256-bit AP-write data string APW-Data, similarly to the P-write data string PW-Data, the number of logic values “1” indicating the rewriting target is counted by the bit calculation circuit B_CAL. The bit calculation circuit B_CAL generates block select signals for designating memory blocks to be simultaneously written and a writing order based on the counting result, and the block select signal and the writing order are supplied to and stored in the lookup table LUT.

Thereafter, the bit calculation circuit B_CAL outputs a cycle signal indicating the writing order to the lookup table LUT in response to an instruction from the bit calculation circuit B_CAL. The write sequencer W_SQR supplies, to the memory array MARY, the mode signal PW/APW-Mode indicating the AP-write mode, a write address for P/AP based on the write address from the processor CPU, and the write command P/AP-Write.

Using the block select signals and the writing order stored in advance, the lookup table LUT selects the block select signal corresponding to the writing order specified with the cycle signal supplied from the write sequencer W_SQR, and sets the selected block select signal to the selection level. Accordingly, as illustrated in FIG. 24C, for example, two or more block select signals are set to the selection level simultaneously, and two or more memory blocks can be simultaneously written across the boundaries between the memory blocks also for the AP-write data string APW-Data.

### Bit Calculation Circuit

Next, the bit calculation circuit according to the first embodiment will be described. The bit calculation circuit B_CAL includes a pop counter circuit PP_CNT and a determination circuit DJ_CKT that executes determination based on a counting result by the pop counter circuit PP_CNT.

The number of memory cells to be simultaneously rewritten is limited to a predetermined number (in the first embodiment, 32) depending on a current supply capability or the like of the booster circuit.

In the P-write mode, the bit calculation circuit B_CAL counts the number of logic values “1” (logic value indicating the rewriting target) included in the P-write data string PW-Data and determines the block select signals to be simultaneously set to the selection level so that the number of signals to be simultaneously set is equal to or less than a predetermined number. Thus, in the bit calculation circuit B_CAL, it is necessary to sequentially examine the 256-bit logic values included in the P-write data string PW-Data by, for example, a clock counter circuit. That is, it is necessary to operate the clock counter circuit for the number of clocks corresponding to 256 bits (the number of cycles), and a counting time becomes long. Since the bit calculation circuit B_CAL also similarly counts the number of logic values “1” in the AP-write data string APW-Data, the counting time becomes longer.

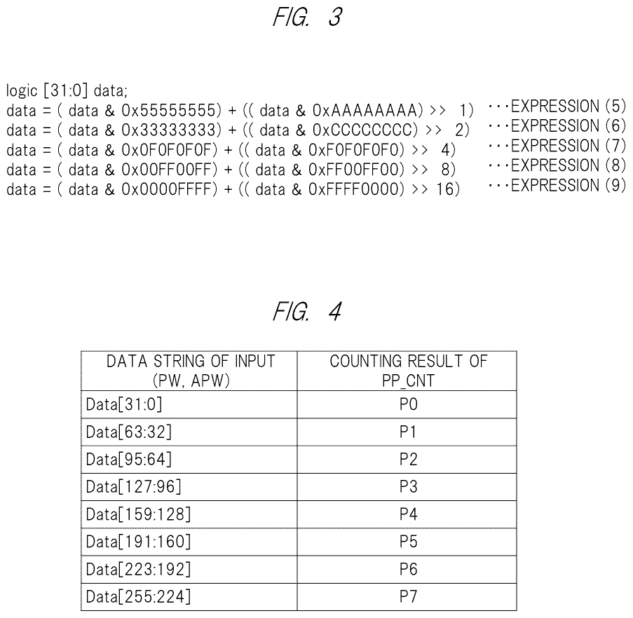

Accordingly, in the bit calculation circuit B_CAL according to the first embodiment, the number of logic values “1” included in the P-write data string PW-Data and the AP-write data string APW-Data is counted by the pop counter circuit PP_CNT. An example of the pop counter circuit PP_CNT will be described with reference to the drawings. FIG. 3 is a diagram illustrating the pop counter circuit according to the first embodiment.

### Pop Counter Circuit

The pop counter circuit PP_CNT according to the first embodiment includes a decoding circuit to which a 32-bit data string is input. The decoding circuit shifts bits of the input and adds bits that are away from each other by a predetermined number of bits. FIG. 3 illustrates logic expressions for realizing the decoding circuit (Expressions (5) to (9)). FIG. 3 illustrates a 32-bit data string Data[31:0] on the least significant side in the 256-bit data string (for example, the P-write data string PW-Data) as the 32-bit data string input to the decoding circuit. Expression (5) indicates addition of logic values that are 1-bit away from each other in the input data string Data. Similarly, Expression (6) indicates addition of logic values that are 2 bits away from each other, and Expressions (7), (8), and (9) indicate addition of logic values that are 4 bits, 8 bits, and 16 bits away from each other, respectively. Accordingly, the number of logic values “1” included in the input 32-bit data string Data[31:0] is output from the decoding circuit. Since Expressions (5) to (9) can be executed simultaneously, it is possible to count the number of logic values “1” included in the 32-bit data string Data[31:0] in one clock (one cycle).

The memory controller MCTR can count the number of logic values “1” included in the P-write data string PW-Data in eight cycles by dividing the 256-bit P-write data string PW-Data every 32 bits into eight pieces and sequentially supplying the eight pieces to the pop counter circuit PP_CNT. Similarly, for the 256-bit AP-write data string APW-Data, the number of logic values “1” included in the AP-write data string APW-Data can be counted in eight cycles.

### Determination Circuit

Based on the counting result of the pop counter circuit PP_CNT, the determination circuit DJ_CKT specifies memory blocks capable of being simultaneously written when the 256-bit data string (the P-write data string PW-Data and the AP-write data string APW-Data) is written. When the 256-bit data string is written, the determination circuit DJ_CKT specifies the writing order when writing is executed in a plurality of cycles based on the counting result.

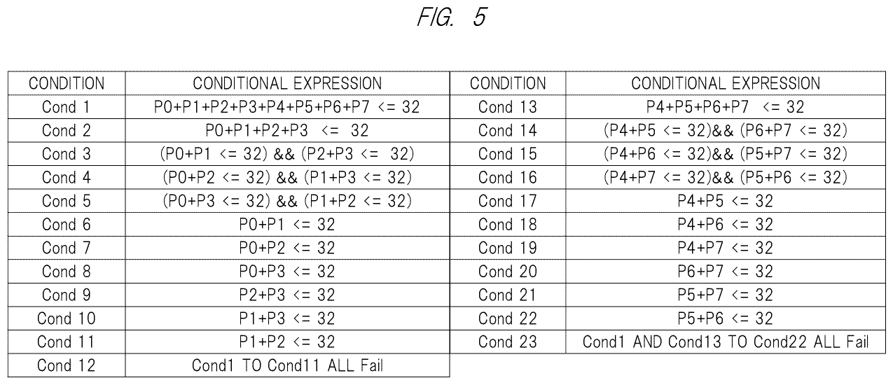

The determination circuit DJ_CKT according to the first embodiment will be described with reference to the drawings. FIGS. 4 to 6 are diagrams illustrating the determination circuit according to the first embodiment.

FIG. 4 illustrates a table of counting results of the pop counter circuit PP_CNT. As described above, the memory controller MCTR divides the 256-bit data string Data[255:0] every 32 bits, and sequentially supplies the divided data strings to the pop counter circuit PP_CNT. Here, as the data string, a P-write data string PW-Data[255:0] will be described as an example. Since the data string is divided every 32 bits and is supplied to the pop counter circuit PP_CNT, the pop counter circuit PP_CNT outputs the numbers of logic values “1” included in the 32-bit P-write data strings PW-Data[31:0] to PW-Data[255:224] (in FIG. 4, referred to as Data[31:0] to Data[255:224]) as P0 to P7. For example, the reference sign P0 indicates the number of logic values “1” included in the 32-bit P-write data string PW-Data[31:0] on the least significant bit side, and the reference sign P7 indicates the number of logic values “1” included in the 32-bit P-write data string PW-Data[255:224] on the most significant side.

Based on the numbers P0 to P7 that are the counting results illustrated in FIG. 4, the determination circuit DJ_CKT executes determination based on conditional expressions illustrated in FIG. 5. That is, the determination circuit executes calculation of each conditional expression of conditions Cond1 to Cond23 using the numbers P0 to P7, and determines whether each conditional expression is satisfied (True=logic value of “1”) or not satisfied (Fail=logic value “0”). In the conditions Cond1 to Cond23, a reference sign “+” indicated in the conditional expression means addition of the numbers, and a reference sign “<=” indicates satisfaction when the value on the right side of the sign is equal to greater than the value on the left side, and indicates non-satisfaction in other cases. In the conditions Cond1 to Cond23, a reference sign “&&” indicates a product of a logic value in ( ) on the left side and a logic value in ( ) on the right side. That is, the reference sign “&&” is satisfied (logic value of “1”) when the conditions in ( ) on the left side and ( ) on the right side are satisfied, and is not satisfied (logic value of “0”) in other cases.

Examples of the conditions Cond1 to Cond23 illustrated in FIG. 5 will be described as follows. For example, in the condition Cond1, the condition Cond1 is satisfied when a sum of the numbers P0 to P7 is equal to or less than 32, and the condition Cond1 is not satisfied when the sum exceeds 32. In the condition Cond3, satisfaction is determined when a sum of the numbers P0 and P1 is equal to or less than 32 and a sum of the numbers P2 and P3 is equal to or less than 32, and non-satisfaction is determined in other cases. In the condition Cond12, satisfaction is determined when all of the conditions Cond1 to (in FIG. 5, the reference sign “˜”) Cond11 are not satisfied, and non-satisfaction is determined in other cases. In the condition Cond23, satisfaction is determined when all of the condition Cond1 and the conditions Cond13 to (In FIG. 5, the reference sign “˜”) Cond22 are not satisfied, and non-satisfaction is determined in other cases.

The determination circuit DJ_CKT executes calculation of the conditional expressions of the conditions Cond1 to Cond23, and determines whether each of the conditions Cond1 to Cond23 is satisfied.

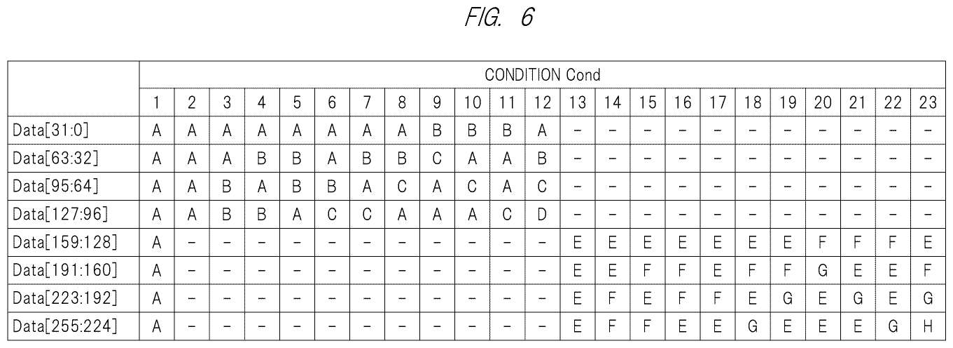

As will be described below, the determination circuit DJ_CKT determines an order of the memory blocks to be written based on each of the determination results of satisfaction and non-satisfaction of the conditions Cond1 to Cond23 and the table illustrated in FIG. 6.

### Writing Order

The determination circuit DJ_CKT first determines whether the condition Cond1 is satisfied. When the condition Cond1 is satisfied, the writing order is specified by the condition Cond1. Conversely, when the condition Cond1 is not satisfied, the determination circuit DJ_CKT according to the first embodiment divides the data strings Data[31:0] to Data[255:224] corresponding to the eight memory blocks MB0 to MB7 into two regions (the data strings Data[31:0] to Data[127:96] and the data strings Data[159:128] to Data[255:224]), and determines an order of the memory blocks to be written for each region.

As understood from FIGS. 4 and 5, the conditions Cond2 to Cond12 are conditions related to the data strings Data[31:0] to Data[127:96] among the data strings Data[31:0] to Data[255:224], and the conditions Cond13 to Cond23 are conditions related to the data strings Data[159:128] to Data[255:224]. Therefore, the writing order of the data strings Data[31:0] to Data[127:96] is specified by the conditions Cond2 to Cond12, and the writing order of the data strings Data[159:128] to Data[255:224] is specified by the conditions Cond13 to Cond23.

In the first embodiment, when a plurality of conditions are satisfied in the conditions Cond2 to Cond12, the writing order of the data strings Data[31:0] to Data[127:96] is specified by a condition with the smallest number among the satisfied conditions. Similarly, when a plurality of conditions are satisfied in the conditions Cond13 to Cond23, the writing order of the data strings Data[159:128] to Data[255:224] is specified by a condition with the smallest number among the satisfied conditions.

FIG. 6 is a table illustrating a relationship between the conditions Cond1 to Cond23, the data strings Data[31:0] to Data[255:224], and writing orders A to H. A horizontal axis of the table represents the conditions Cond1 to Cond23, and a vertical axis represents the data strings Data[31:0] to Data[255:224]. The writing order is set at intersections of the conditions on the horizontal axis and the data strings on the vertical axis.

As described above, since the conditions Cond2 to Cond12 specify the writing order of the data strings Data[31:0] to Data[127:96], the writing orders A to D related to the conditions Cond2 to Cond12 are set at the intersections with the data strings Data[31:0] to Data[127:96] as illustrated in the table of FIG. 6. Similarly, since the conditions Cond13 to Cond23 specify the writing order of the data strings Data[159:128] to Data[255:224], the writing orders E to H related to the conditions Cond13 to Cond23 are set at the intersections with the data strings Data[159:128] to Data[255:224], as illustrated in the table of FIG. 6.

Meanwhile, since the condition Cond1 is related to the eight data strings Data[31:0] to Data[255:224], the writing order A is set at the intersections of the condition Cond1 and each of the data strings Data[31:0] to Data[255:224].

The write operation is executed from the writing order A in the order of A, B, C, D, E, F, G, and H. When the writing orders A to H are all executed, the writing order A is executed earliest and the writing order H is executed latest. The determination circuit DJ_CKT refers to the table of FIG. 6 and specifies the writing order. The write operation is executed simultaneously for a plurality of data strings set to the same writing order (for example, the writing order A).

### Determination Example of Determination Circuit

When the condition Cond1 is satisfied among the conditions Cond1 to Cond23 illustrated on the horizontal axis, the determination circuit DJ_CKT selects a column of the condition Cond1. Since the column of the condition Cond1 intersects with the data strings Data[31:0] to Data[255:224], the determination circuit DJ_CKT generates the block select signals for designating the memory blocks MB0 to MB7 corresponding to the data strings Data[31:0] to Data[255:224] and the writing order, and stores the block select signals and the writing order in the lookup table LUT.

Conversely, when the condition Cond1 is not satisfied and a plurality of conditions among the conditions Cond2 to Cond12 (for example, the conditions Cond2 to Cond5) and a plurality of conditions among the conditions Cond13 to Cond23 (for example, the conditions Cond13 to Cond18) are satisfied, the determination circuit DJ_CKT selects the condition Cond2 having the smallest number among the satisfied conditions Cond2 to Cond5 and the condition Cond13 having the smallest number among the satisfied conditions Cond13 to Cond18.

When the conditions Cond2 and Cond13 are selected, the determination circuit DJ_CKT selects the column of the condition Cond2 in the table of FIG. 6, generates the block select signals for designating the memory blocks MB0 to MB3 corresponding to the data strings Data[31:0] to Data[127:96] intersecting the condition Cond2 and the writing order A, and stores the block select signals and the writing order A in the lookup table LUT. The determination circuit DJ_CKT selects the column of the condition Cond13 in the table of FIG. 6, generates the block select signals for designating the memory blocks MB4 to MB7 corresponding to the data strings Data[159:128] to Data[255:224] intersecting the condition Cond13 and the writing order E, and stores the block select signals and the writing order E in the lookup table LUT.

When the condition Cond1 is not satisfied and a plurality of conditions among the conditions Cond2 to Cond12 (for example, the conditions Cond3 to Cond5) and a plurality of conditions among the conditions Cond13 to 23 (for example, the conditions Cond14 to Cond18) are satisfied, the determination circuit DJ_CKT selects the condition Cond3 having the smallest number among the satisfied conditions Cond3 to Cond5 and the condition Cond14 having the smallest number among the satisfied conditions Cond14 to Cond18.

When the conditions Cond3 and Cond14 are selected, the determination circuit DJ_CKT selects the column of the condition Cond3 in the table of FIG. 6, generates the block select signals for designating the memory blocks MB0 and MB1 corresponding to the data strings Data[31:0] and Data[63:32] intersecting the condition Cond3 and the writing order A, generates the block select signals for designating the memory blocks MB2 and MB3 corresponding to the data strings Data[95:64] and Data[127:96] intersecting the condition Cond3 and the writing order B, and stores the generated signals and orders in the lookup table LUT. In the table of FIG. 6, the determination circuit DJ_CKT selects the column of the condition Cond14, generates the block select signals for designating the memory blocks MB4 and MB5 corresponding to the data string Data[159:128] and Data[191:160] intersecting the condition Cond14 and the writing order E, generates the block select signals for designating the memory blocks MB6 and MB7 corresponding to the data strings Data[223:192] and Data[255:224] intersecting the condition Cond14 and the writing order F, and stores the generated signals and orders in the lookup table LUT.

The bit calculation circuit B_CAL according to the first embodiment can generate the block select signals for designating the memory blocks to be written and the writing order by 29 cycles of calculation that is a total of eight cycles of calculation (P0 to P7 in FIG. 4) by the pop counter circuit PP_CNT and 21 cycles of calculation (conditions Cond1 to Cond11 and Cond13 to Cond22 in FIG. 5) by the determination circuit DJ_CKT. The conditions Cond12 and Cond23 illustrated in FIG. 5 are excluded from the number of cycles of calculation since calculation is unnecessary.

### Data Stored in Look-Up Table by Determination Circuit

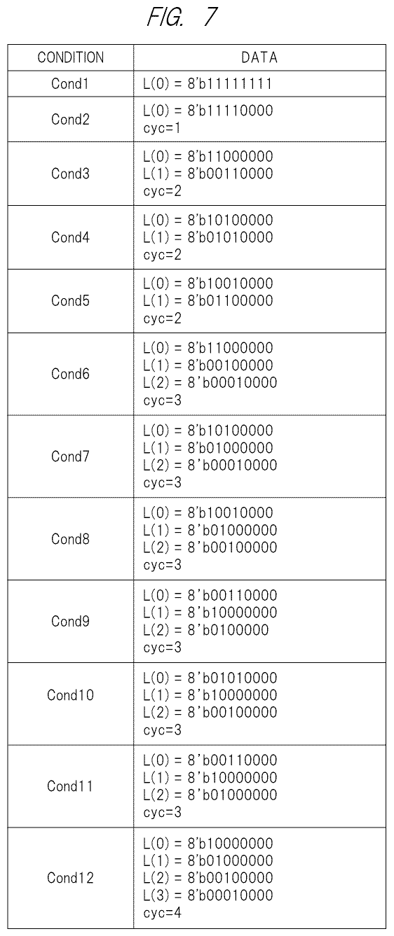

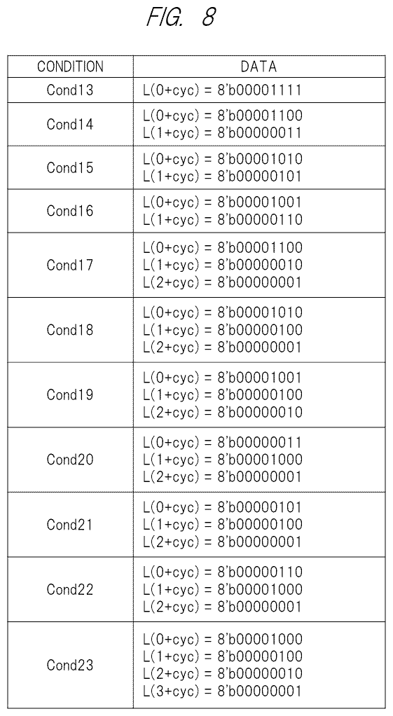

FIGS. 7 and 8 are diagrams illustrating data output from the bit calculation circuit to the lookup table according to the first embodiment. FIG. 7 illustrates the conditions Cond1 to Cond12 and data corresponding thereto, and FIG. 8 illustrates the conditions Cond13 to Cond23 and data corresponding thereto.

Data corresponding to a condition includes one to four pieces of 8-bit (8′b) data. In data corresponding to the conditions Cond1 to Cond12, reference signs “L(0)” to “L(3)” notated on the left side of the reference sign “=” indicate a cycle. That is, the reference signs “L(0)” to “L(3)” indicate a cycle in which writing is executed according to data notated on the right side of the reference sign “=”, and the cycles are executed in the order of the cycles L(0) to L(3). A reference sign “cyc” notated in the data corresponding to the conditions Cond2 to Cond12 indicates the number of cycles. The number of reference signs L(0) to L(3) indicates the number of cycles. For example, when the corresponding expression is only L(0), the number of cycles cyc=1, and when the corresponding expressions are L(0) to L(2), the number of cycles cyc=3. In the condition Cond1, since combination with the conditions Cond13 to Cond23 to be described below does not occur, the number of cycles cyc is not notated and the number of cycles cyc=1.

A reference sign “xxxxxxxx” subsequent to the reference sign “8′b” notated on the right side of the reference sign “=” is a block number for designating the memory blocks MB0 to MB7 (block select signals BL_SL[7:0]). That is, each bit of the 8-bit reference sign “xxxxxxxx” corresponds to each of the memory blocks MB0 to MB7. For example, designation of the memory block MB0 is indicated by “10000000” in which a logic value of “1” is set in the least significant bit, and designation of the memory block MB7 is indicated by “00000001” in which a logic value of “1” is set in the most significant bit. When a plurality of memory blocks are indicated simultaneously, logic values corresponding to the memory blocks are set to “1”.

The expressions corresponding to the conditions Cond13 to Cond23 are also similar to the expressions corresponding to the conditions Cond1 to Cond12. A difference is that the reference signs indicating cycles notated on the left side of the reference sign “=” are “L(0+cyc)” to “L(3+cyc)”. Here, cyc is substituted into the number of cycles of the reference sign “cyc” illustrated in FIG. 7. For example, in data corresponding to the condition Cond13, a cycle notated on the left side of the reference sign “=” is a value obtained by adding the cycle L(0) indicating one cycle to the number of cycles “cyc” illustrated in FIG. 7.

Next, an example of data output from the bit calculation circuit to the lookup table will be described based on the three examples described in <<<<Determination Example of Determination Circuit>>>>.

First, when the condition Cond1 is satisfied, the bit calculation circuit B_CAL supplies 8′b11111111, that is data corresponding to the condition Cond1 illustrated in FIG. 7, to the lookup table LUT, and the lookup table LUT stores the data. In the data, since the eight bits for designating the block number (block select signals) are all set to the logic value of “1”, all the memory blocks MB0 to MB7 are designated in the same cycle.

Subsequently, when the condition Cond1 is not satisfied and the conditions Cond2 and Cond13 are selected, the bit calculation circuit B_CAL combines the data corresponding to the conditions illustrated in FIG. 7 and the data corresponding to the conditions illustrated in FIG. 8 and stores the combined data in the lookup table LUT. That is, the bit calculation circuit B_CAL supplies 8′b11110000, that is data corresponding to the condition Cond2 illustrated in FIG. 7, as data of the first cycle L(0) to the lookup table LUT, and the lookup table LUT stores the data. Thereafter, the bit calculation circuit B_CAL supplies 8′b00001111, that is data corresponding to the condition Cond13 illustrated in FIG. 8, as data of the second cycle L(0+cyc(cyc=1: number of cycles of the condition Cond2)) to the lookup table LUT, and the lookup table LUT stores the data. Accordingly, the data corresponding to the condition Cond2 and the data corresponding to the condition Cond13 are stored in the lookup table LUT in this order.

When the condition Cond1 is not satisfied and the conditions Cond3 and Cond14 are selected, the bit calculation circuit B_CAL supplies 8′b11000000, that is data corresponding to the condition Cond3 illustrated in FIG. 7, as data of the first cycle L(0) to the lookup table LUT, and supplies data 8′b00110000 as data of the second cycle L(1) to the lookup table LUT. Thereafter, the bit calculation circuit B_CAL supplies 8′b00001100, that is data corresponding to the condition Cond14 illustrated in FIG. 8, as data of the third cycle L(0+cyc(cyc=2: number of cycles of the condition Cond3)) to the lookup table LUT, and supplies data 8′b00000011 as data of the fourth cycle L(1+cyc(cyc=2)) to the lookup table LUT. Accordingly, the data 8′b11000000 and 8′b00110000 corresponding to the condition Cond3 and the data 8′b00001100 and 8′b00000011 corresponding to the condition Cond14 are stored in the lookup table LUT in this order.

As such, the bit calculation circuit B_CAL substitutes the number of cycles cyc in the data illustrated in FIG. 7 into the cycles L(0+cyc) to L(3+cyc) illustrated in FIG. 8 to generate the number of cycles of the write operation. The write sequencer W_SQR is notified of the generated number of cycles as the number of write operations when a 256-bit data string is written. The write sequencer W_SQR generates a cycle signal for designating data stored in the lookup table LUT based on the notified number of cycles, and supplies the cycle signal to the lookup table LUT.

### Write Operation for 256-Bit Data String

Next, an operation when a 256-bit data string output from the P/AP-write register P/AP_DR illustrated in FIG. 1 is written to the memory array circuit MARY will be described. The 256-bit data string is, for example, the P-write data string PW-Data[255:0], and of course, may be the AP-write data string APW-Data[255:0]. In the bit calculation circuit B_CAL, it is assumed that the condition Cond1 is not satisfied and the conditions Cond2 and Cond13 are selected.

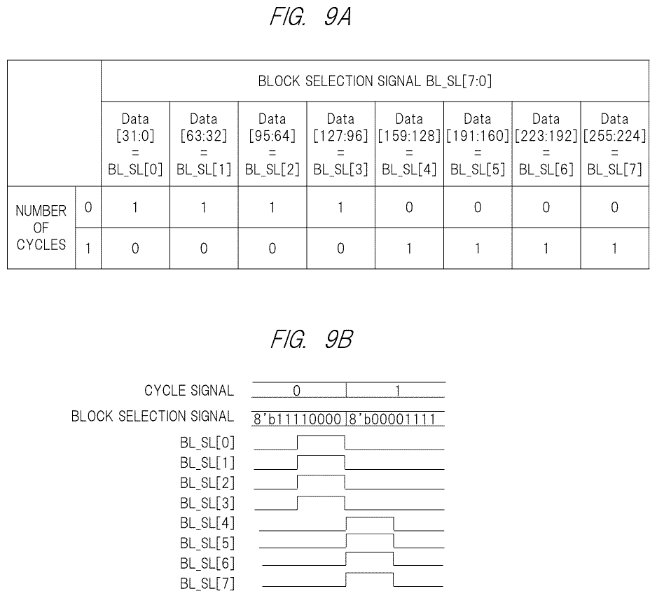

FIGS. 9A and 9B are diagrams illustrating the write operation according to the first embodiment. Here, FIG. 9A illustrates data stored in the lookup table and FIG. 9B illustrates a timing of the write operation.

Since the condition Cond1 is not satisfied and the conditions Cond2 and Cond13 are selected, as described with reference to FIGS. 7 and 8, the bit calculation circuit B_CAL supplies the data 8′b11110000 as data of the first cycle L(0) to the lookup table LUT, and then supplies the data 8′b00001111 as data of the second cycle L(1) to the lookup table LUT. The 8-bit data in the first cycle and the 8-bit data in the second cycle are stored in the lookup table LUT. The 8-bit data is the block select signals BL_SL[7:0] for designating eight memory blocks to which the 256-bit data string is to be written.

Therefore, as illustrated in FIG. 9A, the block select signals BL_SL[7:0], that are data of the number of cycles of 0 that is the first cycle stored in the lookup table LUT, select the memory blocks MB0 to MB3 and do not select the memory blocks MB4 to MB7. On the other hand, the block select signals BL_SL[7:0], that are data of the number of cycles of 1 that is the second cycle, do not select the memory blocks MB0 to MB3 and select the memory blocks MB4 to MB7.

Since the write sequencer W_SQR is notified of the number of cycles from the bit calculation circuit B_CAL, the write sequencer W_SQR supplies a cycle signal for designating the number of cycles of 0 to the lookup table LUT at the number of cycles of 0 that is the first cycle. Accordingly, the block select signals BL_SL[7:0] of the number of cycles of 0 are output from the lookup table LUT. The write sequencer W_SQR supplies a cycle signal for designating the number of cycles of 1 to the lookup table LUT at the number of cycles of 1 that is the second cycle. Accordingly, the block select signals BL_SL[7:0] having the number of cycles of 1 are output from the lookup table LUT.

At the number of cycles of 0 (when the cycle signal is 0), as illustrated in FIGS. 9A and 9B, the block select signals BL_SL[0] to BL_SL[3] have the logic value of 1, and the block select signals BL_SL[4] to BL_SL[7] have the logic value of 0. Therefore, the logic value of 1 is supplied to the AND circuits ALG of the unit input circuits UIN[0] to UIN[31] in the block input circuits BINCKT corresponding to the memory blocks MB0 to MB3. Therefore, when the logic value of 1 indicating rewriting is stored in the FF circuits FF in the unit input circuits, a plurality of memory cells are simultaneously rewritten in the memory blocks MB0 to MB3.

At the number of cycles of 1 (cycle signal is 1), as illustrated in FIGS. 9A and 9B, the block select signals BL_SL[0] to BL_SL[3] have the logic value of 0, and the block select signals BL_SL[4] to BL_SL[7] have the logic value of 1. Therefore, the logic value of 1 is supplied to the AND circuits ALG of the unit input circuits UIN[0] to UIN[31] in the block input circuits BINCKT corresponding to the memory blocks MB4 to MB7. Therefore, when the logic value of 1 indicating rewriting is stored in the FF circuits FF in the unit input circuits, a plurality of memory cells are simultaneously rewritten in the memory blocks MB4 to MB7.

That is, according to FIGS. 9A and 9B, it is possible to simultaneously rewrite the four memory blocks across the boundaries of the memory blocks, and it is possible to suppress an increase in the writing time.

Although it is possible to suppress an increase in the writing time as described above, it is necessary to execute a complicated calculation process in the memory controller MCTR, and there is concern that the start of the write operation with respect to the memory array circuit MARY may be delayed depending on a calculation time required for the calculation process.

The complex calculation executed in the memory controller MCTR is as follows. First, to generate the P-write data string PW-Data and the AP-write data string APW-Data, it is necessary to execute the calculation between the read data string DO_Data[255:0] and the write data string W_Data[255:0]. In the bit calculation circuit B_CAL, it is necessary to execute the calculation by the pop counter circuit PP_CNT and the calculation related to the conditions by the determination circuit DJ_CKT.

As will be described hereinafter with reference to the drawings, to reduce a delay in the start of the write operation due to the calculation time in the semiconductor device according to the first embodiment, the above-described calculations are executed in a transition period in which the mode transitions to the P-write mode and the AP-write mode. The transition period is, for example, a period in which a boosting operation of generating a stable high voltage is executed by the booster circuit and is a time required for the write operation regardless of the complicated calculation described above. By timely overlapping the calculation time with the transition period, it is possible to reduce the delay of the start of the write operation.

### Operation Flow

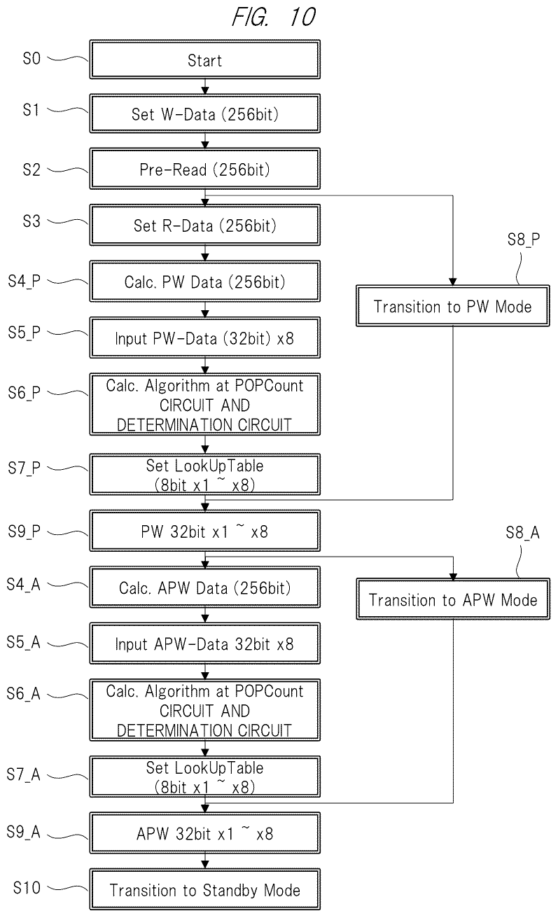

FIG. 10 is a flowchart illustrating an operation of the semiconductor device according to the first embodiment. FIG. 10 illustrates a flow of the write operation. Hereinafter, parallel execution of a calculation process and a mode transition process in the write operation according to the first embodiment will be described with reference to FIGS. 1 and 10.

In step S0, the memory controller MCTR starts the write operation. In step S1, the memory controller MCTR stores the 256-bit write data W-Data from the processor CPU in the write data register W_DR. In the subsequent step S2, the memory controller MCTR reads (pre-reads) 256-bit data stored in an address of the memory array circuit MARY designated with the write address.

Next, the memory controller MCTR executes steps S3 and S4_P to S7_P in this order and also starts step S8_P after step S3 is executed. Accordingly, the processes of steps S3 to S7_P and the process of step S8_P are executed in parallel. Steps S3 to S7_P will be specifically described as follows.

First, in step S3, the memory controller MCTR stores the read data R-Data read in step S2 in the read data register R_DR. In step S4_P, the memory controller MCTR executes a calculation of obtaining the 256-bit P-write data string PW-Data using the write data W-Data stored in the write data register W_DR and the read data R-Data stored in the read data register R_DR, and stores the 256-bit P-write data string PW-Data in the P/AP-write register P/AP_DR.

Subsequently, in step S5_P, the memory controller MCTR divides the 256-bit P-write data string PW-Data stored in the P/AP-write register P/AP_DR into eight (×8) data strings PW-Data (32 bits) every 32 bits by the data-in sequencer D_ISQ and the write selector W_SEL, and supplies the divided P-write data strings PW-Data to the FF circuits FF in the eight block input circuits BINCKT corresponding to the memory blocks MB0 to MB7 (32×8=256). Accordingly, all of 256 bits of the P-write data strings PW-Data is stored in the 256 FF circuits FF corresponding to the memory blocks MB0 to MB7.

In step S6_P, the memory controller MCTR executes the calculation processes described in FIGS. 4 and 5 by the pop counter circuit PP_CNT and the determination circuit DJ_CKT. In step S7_P, the memory controller MCTR stores one to eight (×1 to ×8) pieces of 8-bit data (block select signals BL_SL[7:0]) obtained in step S6_P in the lookup table LUT. Although not particularly limited, in step S7_P, the memory controller MCTR supplies the number of cycles obtained in step S6_P to the write sequencer W_SQR.

Meanwhile, in step S8_P, the mode transitions to the P-write mode. In step S8_P, the memory controller MCTR instructs the booster circuit (not illustrated) to execute a boosting operation of generating a high voltage. A relatively long time is required for the booster circuit to generate a stable high voltage.

Subsequently, in step S9_P, the 8-bit data (block select signals BL_SL[7:0]) specified with the cycle signal from the write sequencer W_SQR are selected from the one to eight (×1 to (in FIG. 10, the reference sign “˜”)×8) pieces of 8-bit data stored in the lookup table LUT, the selected block select signals BL_SL[7:0] are supplied to the eight block input circuits BINCKT corresponding to the memory blocks MB0 to MB7, and the P-write data is simultaneously written to the plurality of memory cells across the boundaries of the memory blocks using the high voltage generated in step S8_P.

Steps S4_A to S7_A and S9_A are similar to steps S4_P to S7_P and S9_P. A difference is that the target data is the AP-write data string APW-Data in steps S4_A to S7_A and S9_A. Since the operations executed in steps S4_A to S7_A and S9_A are the same as those in steps S4_P to S7_P and S9_P, the description thereof will be omitted.

In step S8_A executed in parallel with steps S4_A to S7_A, the modes transitions to the AP-write mode. In step S8_A, the memory controller MCTR instructs the booster circuit (not illustrated) to execute a boosting operation of generating a high voltage. Accordingly, a stable high voltage is generated by the booster circuit.

After the 256-bit data string W-Data is written to the memory array circuit MARY according to steps S0 to S9_A, step S10 is executed. In step S10, the memory controller MCTR transitions from the write operation to a standby mode.

### Configuration Example of Memory Array Circuit

Subsequently, a specific configuration example of the memory array circuit MARY according to the first embodiment will be described with reference to the drawings. Here, a case in which the memory array circuit MARY includes the booster circuit that generates the high voltage used for the write operation will be described, but the present invention is not limited thereto. For example, the booster circuit may be provided in the memory controller MCTR.

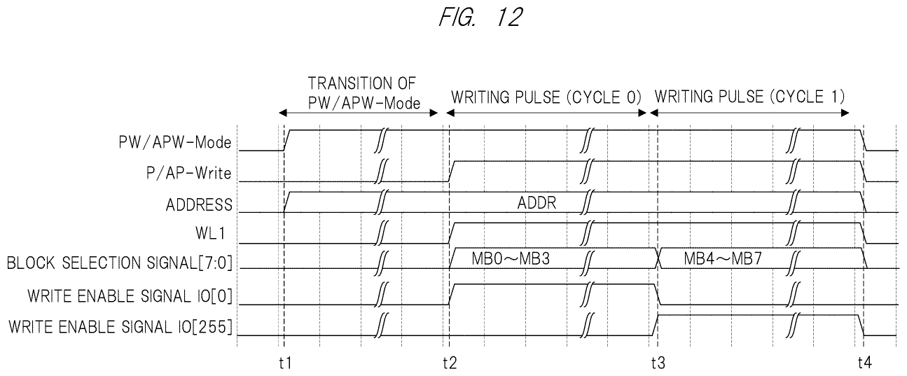

FIG. 11 is a circuit diagram illustrating a configuration example of the memory array circuit according to the first embodiment. FIG. 12 is a timing chart illustrating an operation of the memory array circuit according to the first embodiment. Although the memory controller MCTR is also illustrated in FIG. 11, only the write sequencer W_SQR is illustrated in FIG. 11, and other circuit blocks are omitted.

Although the memory array circuit MARY includes a plurality of circuit blocks, only blocks necessary for description are illustrated in FIG. 11. The memory array circuit MARY includes a booster circuit PWC, a distribution circuit (distributor) DIST, a decoder DEC, a word driver WLD, the memory blocks MB0 to MB7, and the unit input circuits UIN[0] to UIN[31].

Since the memory blocks MB0 to MB7 have similar configurations, the memory block MB0 will be described as an example. The memory block MB0 includes a plurality of memory cells MCL arranged in a matrix form, word lines WL (in FIG. 11, only WL1 is illustrated as a representative) arranged in each row, and pairs of bit lines BL and source lines SL arranged in each column. The memory block MB0 illustrated in FIG. 11 includes 32 columns, although the number is not particularly limited.

The bit line BL and the source line SL of each column are connected to power supply lines VLB and VLS via source-drain paths of N-channel field effect transistors (hereinafter also referred to as transistors) N1 and N2 in a column switch. Gates of the transistors N1 and N2 are connected to the unit input circuits (for example, UIN[0]) corresponding to the bit line BL and the source line SL arranged in each column. The unit input circuits UIN[0] to UIN[31] are configured as illustrated in FIG. 1, and write enable signals (input data) IO[0] to IO[31] output from the unit input circuits are supplied to the gates of the transistors N1 and N2 in the column switch.

The memory cell MCL includes a selection transistor NC and a storage element MTJ. In the selection transistor NC, a gate is connected to the word line WL1 arranged in a row, a drain is connected to the bit line BL via the storage element MTJ, and a source is connected to the source line SL. The storage element MTJ is an element that has a three-layer structure of a magnetic tunneling junction although not particularly limited. The element having the three-layer structure is an element that has a structure in which a pinned layer, a tunneling layer, and a free layer are stacked, and a resistance value of the element changes according to written data.

The word line WL1 arranged in each row is connected to the decoder DEC via the corresponding word driver WLD. A power supply terminal of the word driver WLD is connected to a power supply line WVD, and the word driver WLD supplies an operating voltage or a grounding voltage in the power supply line WVD to the word line WL1 according to a select signal from the decoder DEC.

The booster circuit PWC is common for the memory blocks MB0 to MB7 and one booster circuit PWC is illustrated in FIG. 11. The booster circuit PWC includes a charge pump circuit CPC controlled with a mode signal PW/APW-Mode from the write sequencer W_SQR, and a regulator LDO that stabilizes the high voltage generated in the boosting operation by the charge pump circuit CPC. When the P-write mode or the AP-write mode is instructed with the mode signal PW/APW-Mode, the charge pump circuit CPC starts the boosting operation, and the high voltage generated in the boosting operation is stabilized by the regulator LDO and supplied from the booster circuit PWC to the distribution circuit DIST as the high voltage VCP for writing.

The distribution circuit DIST supplies a high voltage for writing or a grounding voltage VS (for example, 0 V) based on the high voltage VCP supplied from the booster circuit PWC to the power supply lines VLS, VLB, and WVD according to the mode signal PW/APW-Mode.

When the write command P/AP-Write is supplied, the decoder DEC decodes the write address from the write sequencer W_SQR, generates a select signal for selecting a word line specified with the write address, and supplies the select signal to the word driver WLD.

### High Voltage for Writing and Write Operation

The distribution circuit DIST determines voltages to be supplied to the power supply lines VLS, VLB, and WVD according to the mode designated with the mode signal PW/APW-Mode, that is, the P-write mode or the AP-write mode.

That is, in the P-write mode, the distribution circuit DIST supplies a first high voltage VBL0 based on the high voltage VCP from the booster circuit PWC to the power supply line VLB, supplies a first word line voltage VWL0 based on the high voltage VCP to the power supply line WVD, and supplies the grounding voltage VS to the power supply line VLS. Here, when a write enable signal (for example, IO[0]) is set to a high level corresponding to the logic value of 1, the transistors N1 and N2 become conductive, the first high voltage VBL0 is supplied to the bit line BL, and the grounding voltage VS is supplied to the source line SL. Here, when the decoder DEC supplies the high level select signal for designating the word line WL1 to the word driver WLD, the word driver WLD supplies the first word line voltage VWL0 to the word line WL. Accordingly, the selection transistor NC in the memory cell MCL becomes conductive, a current flows from the power supply line VLB to the power supply line VLS via the storage element MTJ and the selection transistor NC, and the resistance value of the storage element MTJ changes. That is, the memory cell MCL is rewritten.

Meanwhile, in the AP-write mode, the distribution circuit DIST supplies a second high voltage VSL1 based on the high voltage VCP to the power supply line VLS, supplies a second word line voltage VWL1 based on the high voltage VCP to the power supply line WVD, and supplies the grounding voltage VS to the power supply line VLB. Here, when a write enable signal (for example, IO[0]) is set to a high level corresponding to the logic value of 1, the transistors N1 and N2 become conductive, the second high voltage VSL1 is supplied to the source line SL, and the grounding voltage VS is supplied to the bit line BL. Here, when the decoder DEC supplies the high level select signal for designating the word line WL1 to the word driver WLD, the word driver WLD supplies the second word line voltage VWL1 to the word line WL. Accordingly, the selection transistor NC in the memory cell MCL becomes conductive, a current flows from the power supply line VLS to the power supply line VLB via the selection transistor NC and the storage element MTJ, and the resistance value of the storage element MTJ changes. That is, the memory cell MCL is rewritten.

When a write enable signal (for example, IO[0]) is set to a low level corresponding to the logic value of 0, the transistors N1 and N2 become non-conductive, the first high voltage VBL0, the second high voltage VSL1, and the grounding voltage VS are not supplied to the bit line BL and the source line SL, and writing (rewriting) of the memory cell MCL is not executed. Similarly, when a select signal supplied from the decoder DEC to the word driver WLD is set to a low level, the selection transistor NC in the memory cell MCL becomes non-conductive, and thus writing (rewriting) of the memory cell MCL is not executed.

As illustrated in FIG. 12, when the P-write mode or the AP-write mode is designated in the memory array circuit MARY according to the mode signal PW/APW-Mode at time t1, mode transition to the P-write mode or the AP-write mode is started. During a mode transition period (a period from time t1 to time t2), the charge pump circuit CPC starts the boosting operation, and the high voltage VCP for writing is stably generated. After mode transition, the distribution circuit DIST supplies the power supply lines with the high voltages (VBL0, VSL1, VWL0, and VWL1) and the grounding voltage VS according to the mode.

Although not particularly limited, a write address ADDR is also supplied to the memory array circuit MARY at time t1, and when the write command P/AP-Write is supplied at time t2, the decoder DEC outputs the select signal for selecting the word line WL1 designated with the address ADDR. Accordingly, the voltage of the word line WL1 becomes a voltage value that causes the selection transistor NC of the memory cell MCL to be conductive.

When the block select signals BL_SL[7:0] as illustrated in FIG. 9A are output from the lookup table LUT illustrated in FIG. 1, the memory blocks MB0 to MB3 are simultaneously selected in a period from time t2 to time t3 illustrated in FIG. 12, and the memory blocks MB4 to MB7 are simultaneously selected in a period from time t3 to time t4.

As a result, the plurality of memory cells arranged in the memory blocks MB0 to MB3 and corresponding to the unit input circuits that output the write enable signal with a high level (for example, IO[0]) are simultaneously rewritten in the period from time t3 to time t4. Similarly, the plurality of memory cells arranged in the memory blocks MB4 to MB7 and corresponding to the unit input circuits that output the write enable signal with a high level (for example, IO[255]) are simultaneously rewritten in the period from time t3 to time t4.

According to the first embodiment, in the period from time t2 to time t3, the number of write enable signals that are simultaneously set to the high level is equal to or less than a predetermined number (32). Similarly, in the period from time t2 to time t3, the number of write enable signals that are simultaneously set to the high level is equal to or less than the predetermined number (32). As a result, it is possible to simultaneously rewrite a plurality of memory cells while limiting a value of resultant currents supplied from the distribution circuit DIST to the memory cells, and it is possible to suppress an increase in the writing time.

### Modification

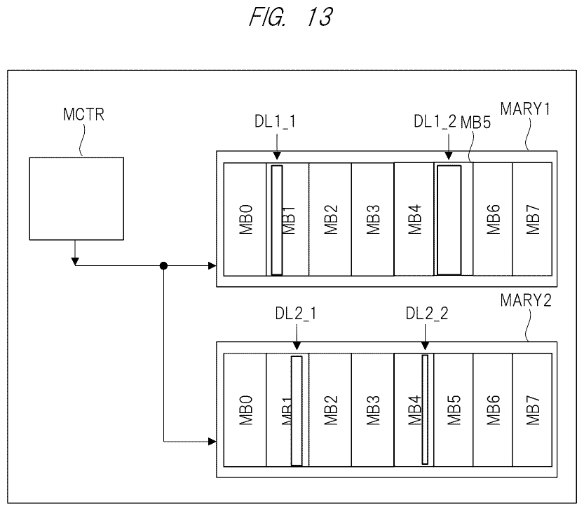

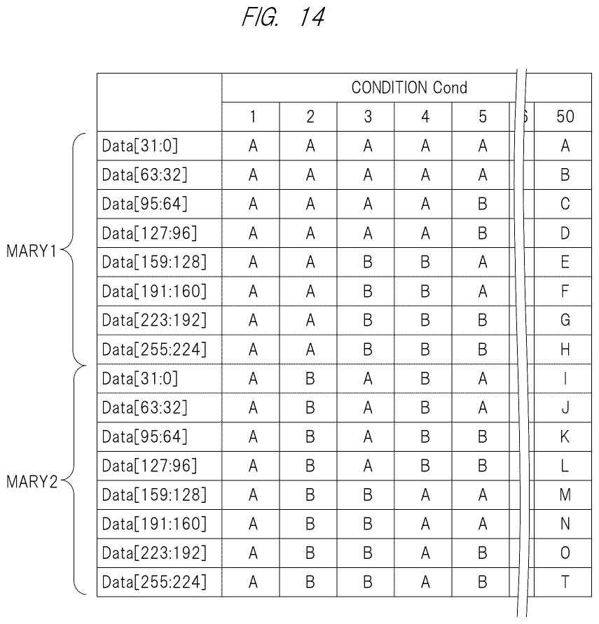

FIGS. 13 and 14 are diagrams illustrating a semiconductor device according to a modification of the first embodiment. FIG. 13 is a block diagram illustrating a configuration of the semiconductor device according to the modification of the first embodiment. FIG. 14 is a diagram illustrating a write operation of the semiconductor device illustrated in FIG. 13. FIG. 14 is similar to FIG. 6 and illustrates an order of memory blocks to be written.

In the modification, the semiconductor device 1 includes two memory array circuits MARY1 and MARY2 and a common memory controller MCTR that controls writing of the two memory array circuits MARY1 and MARY2.

Each of the memory array circuits MARY1 and MARY2 includes eight memory blocks MB0 to MB7, and each memory block is written in a unit of 32 bits.

The memory controller MCTR writes, for example, a 512-bit data string Data to the two memory arrays MARY1 and MARY2 in a distributed manner. In FIG. 13, D1_1 to D2_2 indicate regions to be written in a distributed manner.

The memory controller MCTR divides the 512-bit data string into a 256-bit data string for the memory array circuit MARY1 and a 256-bit data string for the memory array circuit MARY2, and writes each of the divided data strings as 32-bit data strings Data[31:0] to Data[255:224]. During writing, the memory controller MCTR executes the counting described with reference to FIG. 4 so that the number of memory cells to be simultaneous rewritten is equal to or less than a predetermined number and further executes the calculation of the conditions described with reference to FIG. 5. The memory controller MCTR determines memory blocks to be written and a writing order with reference to the table illustrated in FIG. 14 based on the conditions obtained by the calculation, and executes writing to the two memory array circuits MARY1 and MARY2. Also in FIG. 14, as in FIG. 6, the writing order is an alphabetical order.

In FIGS. 13 and 14, two memory array circuits are described as an example, but as long as the number of memory array circuits are plural, the number is not limited to two.

In the first embodiment, since the unit input circuit (for example, UIN[1]) includes the AND circuit ALG and the FF circuit FF as illustrated in FIG. 1, it is possible to suppress an increase in the occupied area of the memory array circuit MARY. The number of memory cells to be rewritten is counted in a unit of memory blocks such as 32 bits, and the memory blocks to be simultaneously written and the writing order are specified, so that even when a period of transition to the P-write mode and the AP-write mode is short, counting of the number of memory cells to be rewritten and the like can be executed in parallel in the transition period.

In the first embodiment, the 256 FF circuits FF corresponding to the memory blocks MB0 to MB7 are divided into a plurality of regions (for example, reference signs A to H in FIG. 6) by the block select signals BL_SL[7:0] output from the lookup table LUT, each of the plurality of divided regions is selected at a different timing (for example, reference signs L(0) to L(3+cyc) in FIGS. 7 and 8), and writing is substantially simultaneously executed according to the data held in the FF circuits FF in the selected regions. Here, the memory controller MCTR according to the first embodiment generates the block select signals BL_SL[7:0] for dividing the 256 FF circuits FF (storage circuits) into a plurality of regions and stores the block select signals BL_SL[7:0] in the lookup table LUT so that the number of FF circuits FF that store the logic value of “1” that is inverted data is equal to or less than a predetermined number (32) among the 256 FF circuits FF. Accordingly, it is possible to limit the number of memory cells to be substantially simultaneously rewritten to be equal to or less than the predetermined number, increase the number of memory cells to be written even with a booster circuit having a low current supply capability, and reduce the number of write cycles and suppress an increase in the writing time.

### Second Embodiment

In the first embodiment, memory blocks to be simultaneously written and a writing order are specified in a unit of memory blocks. In a second embodiment, a region to be simultaneously written and a writing order are specified across memory blocks. For example, in the second embodiment, one memory block is divided into a plurality of (for example, two) regions, and writing is executed at different timings.

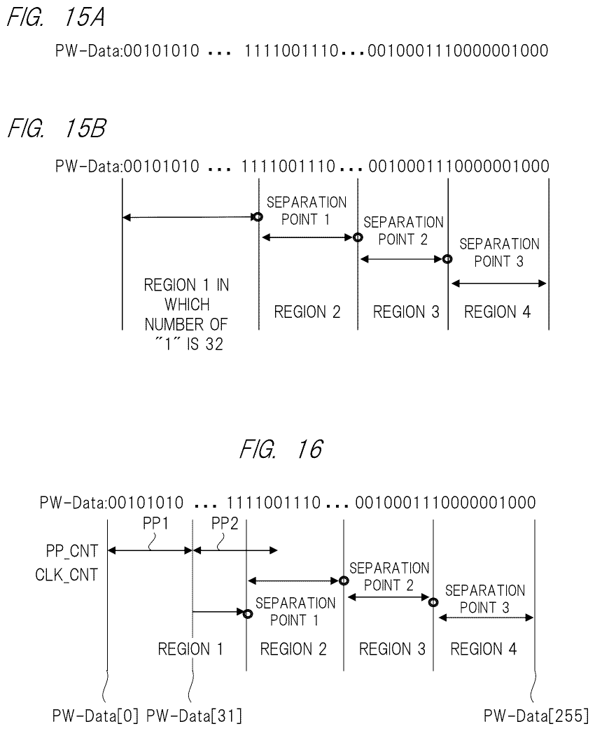

FIGS. 15A and 15B are diagrams illustrating a semiconductor device according to the second embodiment. Like the first embodiment, the memory controller MCTR according to the second embodiment generates the 256-bit P-write data string PW-Data and AP-write data string APW-Data, and stores the data strings in the P/AP-write register P/AP_DR. FIG. 15A illustrates an example of a 256-bit data string stored in the P/AP-write register P/AP_DR. Here, the P-write data string PW-Data will be described as an example, but the same applies to the AP-write data string APW-Data.

The memory controller MCTR according to the second embodiment counts the number of logic values “1” of the 256-bit P-write data string PW-Data stored in the P/AP-write register P/AP_DR from the least significant bit PW-Data[0] to the most significant bit PW-Data[255] by each clock, and divides the P-write data string PW-Data every time the number of logic values “1” reaches a predetermined number (32). Accordingly, the P-write data string PW-Data is divided into one to a maximum of eight regions depending on the number of logic values “1”.

FIG. 15B illustrates an example in which the P-write data string PW-Data is divided into four regions (regions 1 to 4). In the P-write data string PW-Data, bit locations at which the number of logic values “1” reaches the predetermined number are indicated as separation points 1 to 3, the region 1 is a region from the least significant bit to the separation point 1, the region 2 (region 3) is a region from the separation point 1 (separation point 2) to the separation point 2 (separation point 3), and the region 4 is a region from the separation point 3 to the most significant bit.

By obtaining the regions 1 to 4 as such, the memory controller MCTR can simultaneously execute the write operation on the plurality of memory cells in the region 1 without being limited to one memory block while limiting the number of memory cells to be simultaneously rewritten to the predetermined number or less. Similarly, in the regions 2, 3, and 4, the memory cells in each region can be simultaneously written. The writing order is, for example, an order of the regions 1 to 4. Accordingly, it is possible to write the 256-bit P-write data string PW-Data in four cycles and it is possible to suppress an increase in the writing time.

Since the circuit for counting the logic value of “1” can be realized by a clock counter circuit having a small occupied area, the memory controller MCTR can be miniaturized.

### Modification

In FIGS. 15A and 15B, in the 256-bit P-write data string PW-Data, the number of logic values of “1” is counted bit by bit by each clock. Therefore, in the counting of the logic value of “1”, a clock cycle corresponding to the number of bits in the P-write data string PW-Data is required. Therefore, in the method illustrated in FIGS. 15A and 15B, there is a concern that a counting time becomes long.

In a modification, the number of logic values of “1” is counted in a unit of 32 bits by the pop counter circuit PP_CNT. When the number of logic values of “1” exceeds 32 in counting in a unit of 32 bits by the pop counter circuit PP_CNT, the clock counter circuit specifies a separation point by specifying a bit location at which the number of logic values of “1” exceeds 32.

FIG. 16 is a diagram illustrating a semiconductor device according to the modification of the second embodiment. First, a number PP1 of logic values of “1” is counted in the 32-bit data string PW-Data[31:0] on the least significant bit side of the P-write data string PW-Data by the pop counter circuit PP_CNT. Subsequently, a number PP2 of logic values of “1” is counted in the next 32-bit data string PW-Data[63:32] by the pop counter circuit PP_CNT. When a sum of the counted numbers PP1 and PP2 exceeds a predetermined number (32), a clock counter circuit CLK_CNT counts the number of logic values of “1” from a bit location that is one bit after the last bit location PW-Data[31] of the immediately previous data string PW-Data[31:0], and a point at which a sum of the number PP1 counted by the pop counter circuit PP_CNT and a number counted by the clock counter circuit CLK_CNT reaches the predetermined number is specified as the separation point 1.

Subsequently, the pop counter circuit PP_CNT starts counting in a unit of 32-bit data strings starting from the separation point 1, and when the number counted by the pop counter circuit PP_CNT exceeds the predetermined number, the clock counter circuit CLK_CNT performs counting to specify the separation point 2. Subsequently, the separation point 3 is specified in the same way.

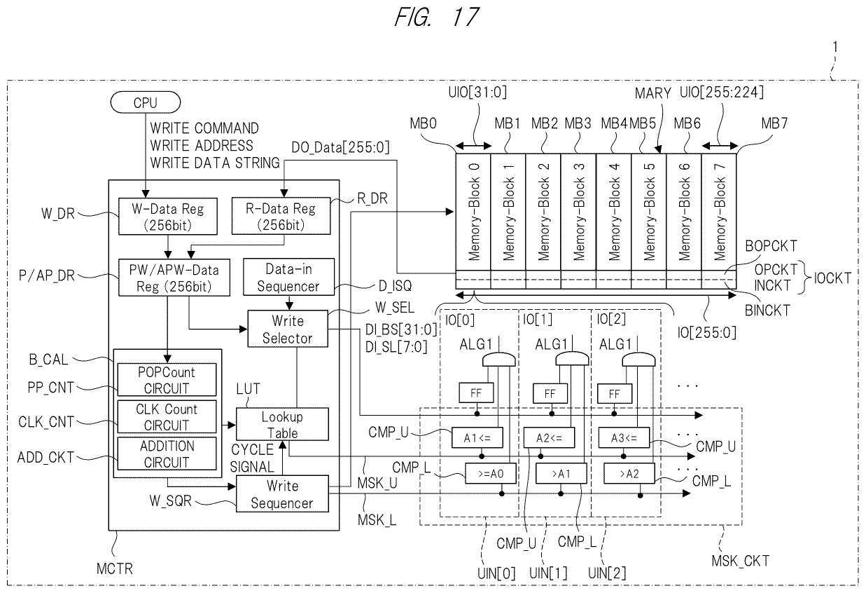

FIG. 17 is a block diagram illustrating a configuration of the semiconductor device according to the modification of the second embodiment. FIG. 17 is similar to FIG. 1. A main difference between FIG. 17 and FIG. 1 is that, in FIG. 17, the bit calculation circuit B_CAL, the block input circuits BINCKT corresponding to each of the memory blocks MB0 to MB7, and the lookup table LUT are changed from those in FIG. 1.

As illustrated in FIG. 17, the bit calculation circuit B_CAL includes the pop counter circuit PP_CNT, the clock counter circuit CLK_CNT, and an addition circuit ADD_CKT. As described with reference to FIGS. 15A and 15B, the memory controller MCTR counts the number of logic values of “1” in a unit of 32-bit data strings by the pop counter circuit PP_CNT.

When the counted number of logic values of “1” (PP1+PP2) exceeds the predetermined number (32) in the counting by the pop counter circuit PP_CNT, the memory controller MCTR counts the number of logic values of “1” by the clock counter circuit CLK_CNT from a bit location that is one bit after the immediately previous 32-bit data string, adds the number of logic values of “1” counted by the pop counter circuit PP_CNT and the number of logic values “1” counted by the clock counter circuit CLK_CNT by the addition circuit ADD_CKT, and specifies a bit location in the P-write data string PW-Data in which the counted number reaches the predetermined number (32) as a separation point.

The memory controller MCTR specifies separation points in all bits of the P-write data string PW-Data by the bit calculation circuit B_CAL, stores the specified separation points (in the example of FIG. 16, the separation points 1 to 3) in the lookup table LUT, and notifies the write sequencer W_SQR of a number of specified separation points +1 as the number of cycles.

Like FIG. 1, each block input circuit BINCKT includes 32 unit input circuits UIN. FIG. 17 illustrates three unit input circuits UIN[0] to UIN[2] in the block input circuit BINCKT corresponding to the memory block MB0. Since the 32 unit input circuits according to the modification have the same configuration, the unit input circuit UIN[0] will be described here as an example.

The unit input circuit UIN[0] includes a 3-input AND circuit ALG1, the FF circuit FF, and two comparators (upper-side comparator and lower-side comparator) CMP_U and CMP_L. The AND circuit ALG1 is supplied with an output of the FF circuit FF, an output of the upper-side comparator CMP_U, and an output of the lower-side comparator CMP_L. An output of the AND circuit ALG1 is the write enable signal (input data) IO[0] like the output of the AND circuit ALG illustrated in FIG. 1. Similarly to the FF circuit FF illustrated in FIG. 1, the FF circuit FF stores data to be written in advance.

The lower-side comparator CMP_L compares a bit location A0 corresponding to the least significant bit location PW-Data[0] in the P-write data string PW-Data with a lower-side mask signal MSK_L, and outputs a comparison result to the AND circuit ALG1. The upper-side comparator CMP_U compares a bit location A1 corresponding to a subsequent bit location PW-Data[1] on the upper side with an upper-side mask signal MSK_U, and outputs a comparison result to the AND circuit ALG1. Here, the bit locations A0 and A1 can be regarded as specification information for specifying a region in the unit input circuit UIN[0] in which the FF circuit FF is arranged.

Other unit input circuits (for example, the unit input circuits UIN[1] and UIN[2]) are similar to the unit input circuit UIN[0] except that bit locations to be compared by the lower-side comparator CMP_L and the upper-side comparator CMP_U are different. For example, the lower-side comparator CMP_L in the unit input circuit UIN[1] compares the bit location A1 corresponding to the unit input circuit UIN[1] with the lower-side mask signal MSK_L, and the upper-side comparator CMP_U compares an upper-side bit location A2 with the upper-side mask signal MSK_U.

The upper-side mask signal MSK_U and the lower-side mask signal MSK_L are output from the lookup table LUT. That is, the separation points stored in the lookup table LUT are output as the upper-side mask signal MSK_U and the lower-side mask signal MSK_L.

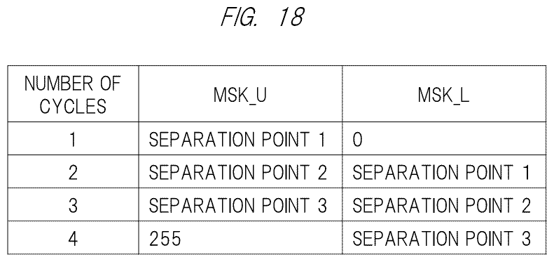

FIG. 18 is a diagram illustrating the lookup table LUT according to the modification of the second embodiment. As described above, separation points specified by the bit calculation circuit B_CAL are stored in the lookup table LUT. FIG. 18 illustrates an example in which the separation points 1 to 3 illustrated in FIG. 16 and the number of cycles of which the write sequencer W_SQR is notified are stored in the lookup table LUT.

The regions 1 to 4 illustrated in FIG. 16 are specified by the upper-side mask signal MSK_U and the lower-side mask signal MSK_L. The lookup table LUT outputs the separation points as the upper-side mask signal MSK_U and the lower-side mask signal MSK_L in the order of the number of cycles of 1 to 4 according to the cycle signals from the write sequencer W_SQR. For example, in the number of cycles of 1, the lookup table LUT outputs the separation point 1 as the upper-side mask signal MSK_U and outputs numerical value 0 as the lower-side mask signal MSK_L. Accordingly, the plurality of unit input circuits in a range from the numerical value 0 to the separation point 1 (range of the region 1) are simultaneously selected, and the plurality of memory cells can be simultaneously written. Here, the write enable signal is set to the logic value of “1” for the memory cells for which the logic value of “1” is stored in the FF circuit FF, and the memory cells are rewritten. The number of memory cells to be rewritten in the region 1 is 32, that is a predetermined number. Here, regions outside of the region 1 are masked, and thus, even when the logic value of “1” is stored in the FF circuit FF in the memory cells of the outside regions, the write enable signal is set to the logic value of “0”, and the memory cells are not rewritten.

Thereafter, ranges of the regions 2 to 4 are sequentially selected in the order of the number of cycles of 2 to 4, and a plurality of memory cells are simultaneously written. As a result, a 256-bit data string (for example, the P-write data string PW-Data) is written in four cycles.

Here, the P-write data string is described as an example, but the same applies to the AP-write data string.

Although the modification is described with reference to FIG. 17, the second embodiment described in FIG. 15B can be realized in FIG. 17 by deleting the pop counter circuit PP_CNT and the addition circuit ADD_CKT from the bit calculation circuit B_CAL, counting the number of logic values of “1” in the P-write data string and the AP-write data string by the clock counter circuit CLK_CNT, and dividing the data strings for every 32 bits.

In the second embodiment, the 256 FF circuits FF are divided into a plurality of regions (for example, the regions 1 to 4 in FIGS. 15B and 16) by the mask signals MSK_U and MSK_L output from the lookup table LUT, each of the plurality of divided regions is selected at a different timing (for example, the number of cycles of 1 to 4 in FIG. 18), and writing is substantially simultaneously executed according to data held by the FF circuits FF in the selected regions. Here, the memory controller MCTR according to the second embodiment specifies separation points for dividing the 256 FF circuits FF (storage circuits) into a plurality of regions so that the number of FF circuits FF that store inverted data is equal to or less than a predetermined number (32) among the 256 FF circuits FF. Accordingly, it is possible to limit the number of memory cells to be substantially simultaneously rewritten to be equal to or less than the predetermined number, increase the number of memory cells to be written even with a booster circuit having a low current supply capability, and reduce the number of write cycles and suppress an increase in the writing time.

### Third Embodiment

According to the second embodiment, it is possible to suppress an increase in the writing time by specifying the regions to be written with the separation points. However, for example, in FIG. 17, two comparators CMP_U and CMP_L are required for each unit input circuit, and there is a concern that the occupied area increases.

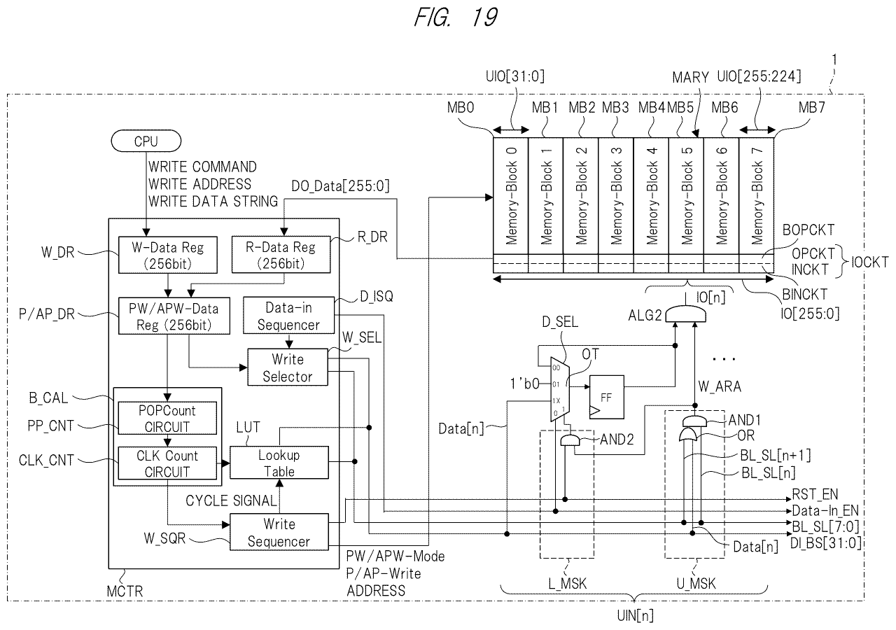

FIG. 19 is a block diagram illustrating a configuration of a semiconductor device according to a third embodiment. FIG. 19 is similar to FIGS. 1 and 17. A main difference from FIG. 1 is that, in FIG. 19, the data-in sequencer D_ISQ, the write selector W_SEL, the lookup table LUT, the write sequencer W_SQR, the bit calculation circuit B_CAL, and the unit input circuit are changed.

First, the unit input circuit will be described. The memory array circuit MARY includes 256 unit input circuits UIN[0] to UIN[255] to correspond to 256-bit input data (write enable signals) IO[255:0]. Since the unit input circuits are similar to each other, the unit input circuit UIN[n] will be described as a representative example. The unit input circuit UIN[n] includes AND circuits ALG2, AND1, and AND2, an OR circuit OR, the FF circuit FF, and a data selector D_SEL.

In FIG. 19, a reference sign U_MSK indicates an upper mask circuit that realizes a function corresponding to a function realized by the upper-side mask signal and the upper-side comparator CMP_U described in the modification of the second embodiment, that is, a function of allowing the write enable signal to be set to the logic value of “1” on the lower side from the separation point. The upper mask circuit U_MSK includes the AND circuit AND1 and the OR circuit OR. Here, an input of the OR circuit OR is connected to the input data Data[n] and the block select signal BL_SL[n+1] in the input data bus DI_BS[31:0], and an input of the AND circuit AND1 is connected to an output of the OR circuit OR and the block select signal BL_SL[n]. An output of the AND circuit AND1 is a write region signal W_ARA that is an output of the upper mask circuit U_MSK.

In FIG. 19, a reference sign L_MSK indicates a lower mask circuit that realizes a function corresponding to a function realized by the lower-side mask signal and the lower-side comparator CMP_L described in the modification of the second embodiment, that is, a function of prohibiting the write enable signal from being set to the logic value of “1” on the lower side from the separation point. The lower mask circuit L_MSK includes the AND circuit AND2, and an input of the AND circuit AND2 is connected to the write region signal W_ARA and a reset enable signal RST_EN.

The data selector D_SEL includes two selection terminals S0 and S1 (in FIG. 19, the reference sign S is omitted and the reference sign 0 and the reference sign 1 are notated), three input terminals 00, 01, and 1X, and an output terminal OT. According to the logic values supplied to the selection terminals S0 and S1, the data selector D_SEL selects one input terminal from the three input terminals, and electrically connects the selected input terminal to the output terminal OT.

That is, when a data-in enable signal Data-In_EN supplied to the selection terminal S0 is set to the logic value of “1” and an output of the AND circuit AND2 supplied to the selection terminal S1 is set to the logic value of “0”, the data selector D_SEL outputs the data Data[n] in the input data bus DI_BS[31:0] connected to the input terminal 1X from the output terminal OT. When the data-in enable signal Data-In_EN at the selection terminal S0 is set to the logic value of “0” and the output of the AND circuit AND2 at the selection terminal S1 is set to the logic value of “0”, the data selector D_SEL outputs 1-bit data output from the FF circuit FF connected to the input terminal 00 to the output terminal OT. When the data-in enable signal Data-In_EN at the selection terminal S0 is set to the logic value of “0” and the output of the AND circuit AND2 at the selection terminal S1 is set to the logic value of “1”, the data selector D_SEL outputs the 1-bit logic value of “0” supplied to the input terminal 01 to the output terminal OT.

The FF circuit FF stores and outputs 1-bit logic value data output from the data selector D_SEL.

The output of the FF circuit FF and the write region signal W_ARA are supplied to an input of the AND circuit ALG2, and an output of the AND circuit ALG2 is the write enable signal (input data) IO[n].

The data-in enable signal Data-In_EN is output from the data-in sequencer D_ISQ and is set to the logic value of “1” when the P-write data or the AP-write data is stored in the FF circuit FF.

The input data bus DI_BS[31:0] and the block select signals BL_SL[7:0] are connected to the write selector W_SEL and the lookup table LUT. The reset enable signal RST_EN is output from the write sequencer W_SQR.

In the first embodiment, as illustrated in FIG. 1, the input data buses DI_BS[31:0] and the input data selection lines DI_SL[7:0] are used to store the P-write data or the AP-write data in the FF circuit FF, and the block select signals BL_SL[7:0] are used to select the write region. Meanwhile, in FIG. 19, the input data buses DI_BS[31:0] and the block select signals BL_SL[7:0] are used for both the selection when storing of the P-write data or the AP-write data in the FF circuit FF and the selection of the write region. Accordingly, the number of buses to be arranged can be reduced, and an increase in the occupied area can be suppressed.

In the unit input circuit UIN[n] illustrated in FIG. 19, the function of specifying the separation point on the upper side of the write region is realized in the upper mask circuit U_MSK, and after the P-write data or the AP-write data held in the FF circuit FF is written, the FF circuit FF is reset to the logic value of “0” in the lower mask circuit L_MSK, and the separation point on the lower side of the write region is specified. As such, by setting the logic value stored in the FF circuit FF to “0”, the write enable signal is prohibited from being set to the logic value “1”, and rewriting is not executed. As a result, the separation point on the lower side of the write region is substantially specified in the lower mask circuit L_MSK.

Although the unit input circuit UIN[n] is described as an example, the other unit input circuits have the same configuration except that the bit location of Data connected to the data selector D_SEL and the OR circuit OR and the block select signal to which the OR circuit OR and the AND circuit AND1 are connected are different according to the corresponding memory block and the corresponding write enable signal.

As illustrated in FIG. 19, the bit calculation circuit B_CAL includes the pop counter circuit (first counter circuit) PP_CNT and the clock counter circuit (second counter circuit) CLK_CNT. The memory controller MCTR counts the number of logic values of “1” in a unit of 32 bits by the pop counter circuit PP_CNT and executes counting until the number of logic values of “1” reaches a predetermined number. When the number of logic values of “1” exceeds the predetermined number in the counting by the pop counter circuit PP_CNT, the memory controller MCTR counts the number of logic values of “1” in the clock counter circuit CLK_CNT in a region in a unit of 32 bits immediately after a bit position in which the number is exceeded. The memory controller MCTR specifies a bit location having the logic value of “1” in which the number of logic values of “1” counted by the clock counter circuit CLK_CNT reaches the predetermined number.

In FIG. 19, the memory controller MCTR indicates a result of the counting in a unit of 32 bits by the pop counter circuit PP_CNT by the logic value of “1” of the corresponding block select signals. For example, when the counting result of the lowermost P-write data string PW-Data[31:0] is equal to or less than the predetermined number, the lowermost block select signal BL_SL[0] is set to the logic value of “1”.
The memory controller MCTR generates a 32-bit input data string Data reflecting the bit location of the logic value of “1” specified by the clock counter circuit CLK_CNT. The block select signals and the input data string Data generated by the bit calculation circuit B_CAL are supplied and stored in the lookup table LUT.

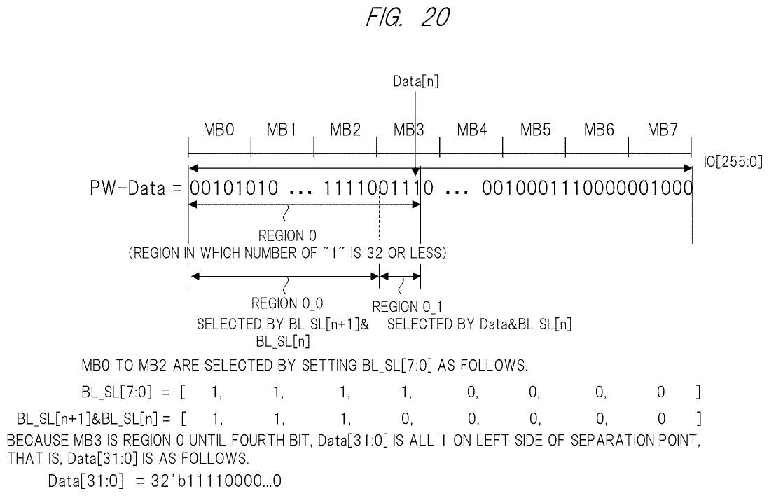

Next, an operation example will be described with reference to the drawings. FIG. 20 is a diagram illustrating the semiconductor device according to the third embodiment.

In FIG. 20, in the P-write data string PW-Data, data of a bit location in which the number of logic values of “1” reaches the predetermined number is denoted as Data[n]. In the example of FIG. 20, the bit location of Data[n] is in a 32-bit data string stored in the memory block MB3.

The memory controller MCTR specifies that the number of logic values of “1” exceeds the predetermined number in the counting of the memory blocks MB0 to MB3 by the pop counter circuit PP_CNT in the bit calculation circuit B_CAL, and sets the block select signals BL_SL[7:0] corresponding to the memory blocks MB0 to MB3 to [1, 1, 1, 1, 0, 0, 0, 0]. The block select signal corresponding to the memory block having the separation point (MB3 in the example) and the memory blocks on the left side thereof (MB0 side) are all set to “1”. The memory controller MCTR specifies that the number of logic values of “1” exceeds the predetermined number in the counting of the memory block MB3 by the pop counter circuit PP_CNT, and counts the number of logic values “1” of the memory block MB3 by the clock counter circuit CLK_CNT. When the number of logic values of “1” reaches the predetermined number in the counting of the clock counter circuit CLK_CNT, the memory controller MCTR specifies a bit location at which the number of logic values reaches the predetermined number in the 32 bits corresponding to the memory block MB3. In the example of FIG. 20, a bit location of a fourth bit is specified. The memory controller MCTR generates the input data string Data[31:0]=32′b11110000 . . . 0 by setting all bits on the left side (least significant side) from the specified bit location (fourth bit) to a logic value of “1” and setting all bits on the right side (most significant side) from the fifth bit to the logic value “0”.

The block select signals generated by the memory controller MCTR is supplied to the upper mask circuit U_MSK in the unit input circuit UIN[n] illustrated in FIG. 19. The memory block on the left side (MB0 side) of the memory block having the separation point is selected according to a result of a logic product calculation in a unit of bits between the block select signal BL_SL[n] and the block select signal BL_SL[n+1]. By the calculation, the block select signal BL_SL[n+1]&BL_SL[n]=[1, 1, 1, 0, 0, 0, 0, 0] for selecting the memory blocks MB0 to MB2 is generated. Accordingly, as illustrated in FIG. 20, a first region 0_0 included in a region 0 is selected.

The input data string Data[31:0] generated by the memory controller MCTR is supplied to the input data buses DI_BS[31:0]. In the memory block having the separation point, a logic product calculation in a unit of bits is executed between the block select signal BL_SL[n] and the input data string Data[31:0]. By the logic product calculation, as illustrated in FIG. 20, a second region 0_1 included in the region 0 is selected.

In the region 0, the write region signal W_ARA is set to the logic value of “1”. As a result, when the logic value of “1” is stored in the FF circuit FF, the write enable signal IO[n] is set to the high level, and rewriting is executed.

After the writing, the write sequencer W_SQR sets the reset enable signal RST_EN to the logic value of “1”. When both the write region signal W_ARA and the reset enable signal RST_EN are set to the logic value of “1”, the data selector D_SEL supplies the logic value of “0” supplied to the input terminal 01 to the FF circuit FF, and resets the data of the FF circuit FF to the logic value of “0”. Accordingly, even when the write region signal W_ARA is set to the logic value of “1” in a subsequent cycle, the write enable signal IO[n] is set to the logic value “0”, and the rewrite operation is not executed.

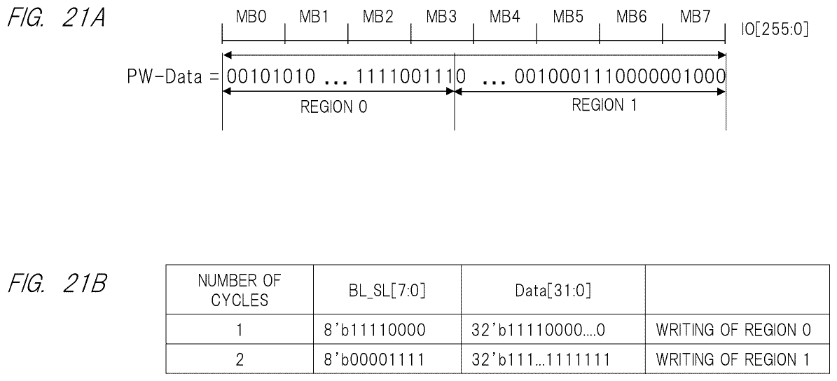

FIGS. 21A and 21B are diagrams illustrating the write operation according to the third embodiment. FIGS. 21A and 21B illustrate a case in which the 256-bit P-write data string PW-Data is written. Of course, the same applies to the AP-write data string APW-Data. In FIGS. 21A and 21B, as illustrated in FIG. 20, the separation point is specified in the fourth bit of the memory block MB3, and FIG. 21A illustrates a case in which data of the region 0 on the lower side from the separation point is simultaneously written and data of the region 1 on the upper side from the separation point is simultaneously written.

Here, the block select signals BL_SL[7:0] and the input data string Data[31:0] as illustrated in FIG. 21B are stored from the bit calculation circuit B_CAL in the lookup table LUT. During the write operation, the block select signals BL_SL[7:0] and the input data string Data[31:0] are selected in the order of the number of write cycles of 1 and 2 by the cycle signal from the write sequencer W_SQR and are supplied to the 256 unit input circuits UIN[0] to UIN[255], and the write operation is executed.

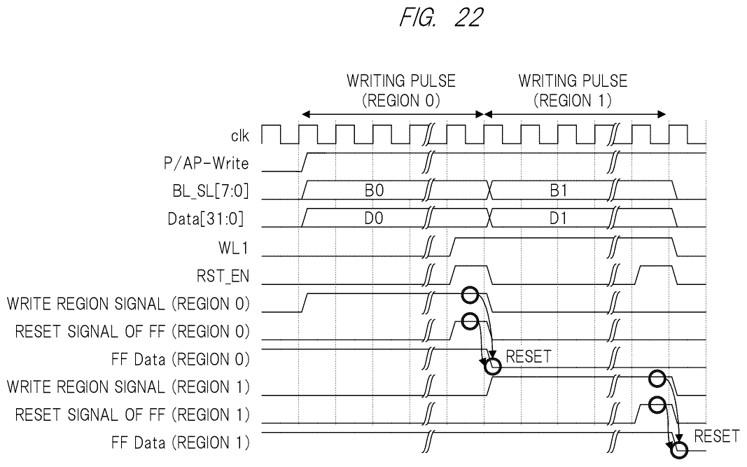

FIG. 22 is a timing chart illustrating the write operation according to the third embodiment. In FIG. 22, clk represents a clock signal, and for example, the charge pump circuit CPC (FIG. 11) and the like operates in synchronization with the clock signal.

The write operation is started by issuing the write command P/AP-Write (changing to the logic value of “1” in FIG. 22). The block select signals BL_SL[7:0] for sequentially designating a plurality of memory blocks B0 and B1 and an input data string Data[31:0] sequentially indicating input data D0 and D1 are supplied from the memory controller MCTR to the memory array circuit MARY.

In the 256 unit input circuits UIN, based on the block select signal BL_SL[7:0] for designating the memory block B0 and the input data string Data[31:0] indicating the input data D0, the write region signal W_ARA for designating the region 0 is set to the logic value of “1”, the write enable signal corresponding to the FF circuit FF corresponding to the region 0 in which the logic value of “1” is stored is set to the logic value of “1”, and the rewriting is executed. Thereafter, when the reset enable signal RST_EN is set to the logic value of “1”, the FF circuit FF corresponding to the region 0 is reset.

Thereafter, similarly to the region 0, rewriting of the region 1 and resetting of the corresponding FF circuit FF are executed.

An operation flow of the semiconductor device according to the third embodiment is similar to the operation flow of the first embodiment illustrated in FIG. 10. A difference is that in the third embodiment, the clock counter circuit CLK_CNT is used instead of the determination circuit in steps S6_P and S6_A, and the input data string Data[31:0] and the block select signals BL_SL[7:0] are stored in the lookup table LUT in steps S7_P and S7_A. Further, in the third embodiment, in steps S5_P and S5_A, the data-in sequencer D_ISQ enables the data-in enable signal Data-In_EN (FIG. 19) (sets to the logic value of “1”). Accordingly, the data selector D_SEL illustrated in FIG. 19 selects the input terminal 1X, and the corresponding input data on the input data bus DI_BS[31:0] is stored in the FF circuit FF.

In the second and third embodiments, since counting is executed until the number of memory cells to be rewritten reaches a predetermined number, it is possible to flexibly select regions to be simultaneously written and optimize the region to be written.

In the third embodiment, 256 FF circuits FF are divided into a plurality of regions (for example, the regions 0 and 1 in FIGS. 20, 21A, and 21B) by the block select signals BL_SL[7:0] and the input data string Data[31:0] output from the lookup table LUT, each of the plurality of divided regions is selected at a different timing (for example, the number of cycles 1 and 2 in FIG. 21B), and writing is substantially simultaneously executed according to data held by the FF circuit FF in the selected regions. Also in the memory controller MCTR according to the third embodiment, the 256 FF circuits FF (storage circuits) are divided into a plurality of regions so that the number of FF circuits FF that store inverted data is equal to or less than the predetermined number (32) among the 256 FF circuits FF. Accordingly, it is possible to limit the number of memory cells to be substantially simultaneously rewritten to be equal to or less than the predetermined number, increase the number of memory cells to be written even with a booster circuit having a low current supply capability, and reduce the number of write cycles and suppress an increase in the writing time.

In the embodiments, examples in which a storage circuit (FF circuits FF) correspond to a data line are described, but the present invention is not limited thereto. That is, the storage circuit may correspond to data to be written. For example, when the number of pieces of data to be simultaneously written is less than the number of data lines, the number of storage circuits is less than the number of data lines.

Although the invention made by the present inventors is specifically described based on the embodiments, the present invention is not limited to the above embodiments, and it goes without saying that various modifications can be made without departing from the gist of the present invention.

What is claimed is:

1. A semiconductor device comprising:
a memory array circuit configured to include a plurality of data lines, a plurality of memory cells connected to the plurality of data lines, and an input circuit that includes a plurality of storage circuits, is supplied with a high voltage during writing, and writes data to the memory cells according to data held in the storage circuits; and
a memory controller configured to supply a data string having a number of pieces of data corresponding to a number of the storage circuits to the input circuit and cause the plurality of storage circuits to hold the data string,
wherein inverted data that changes a state of the memory cell by writing to the memory cell and non-inverted data that does not change the state of the memory cell are mixed in the data string, and
wherein the memory controller
includes a counter circuit that counts a number of pieces of the inverted data included in the data string, and
controls the input circuit to divide the plurality of storage circuits that store the data string into a plurality of regions so that the number of storage circuits that store the inverted data is equal to or less than a predetermined number based on counting by the counter circuit, select the plurality of regions at different timings, and simultaneously write data held in the storage circuits arranged in the selected regions.

2. The semiconductor device according to claim 1,
wherein the memory array circuit includes a booster circuit that generates the high voltage during writing, and
wherein the memory cell is a variable-resistance type memory cell in which a resistance value is determined according to written data, the resistance value being the state.

3. The semiconductor device according to claim 2,
wherein the memory array circuit includes a plurality of memory blocks including n data lines and a plurality of memory cells connected to the n data lines, a plurality of block input circuits corresponding to the plurality of memory blocks, and a plurality of block selection lines corresponding to the plurality of memory blocks,
wherein the block input circuit includes n storage circuits and a logic circuit connected to the storage circuits, the block selection lines, and the data lines,
wherein the memory controller includes
a determination circuit that determines a plurality of regions in which the number of storage circuits that store the inverted data is equal to or less than the predetermined number based on counting of the counter circuit, and
a table that stores block selection information for designating regions selected from the plurality of regions determined by the determination circuit and order information indicating an order of the block selection information, and
wherein the block selection information is output from the table to the block selection lines in an order indicated by the order information stored in the table, and data is written to the memory cells in the memory block designated with the block selection information.

4. The semiconductor device according to claim 3,
wherein the determination circuit executes determination during a period in which the booster circuit executes a boosting operation.

5. The semiconductor device according to claim 4,
wherein the data string stored in the plurality of storage circuits is a data string obtained by a calculation between a data string read from the memory array circuit and a data string to be written.

6. The semiconductor device according to claim 5,
wherein the counter circuit includes a pop counter circuit supplied with a plurality of pieces of data to be stored in the n storage circuits in the block input circuit in the data string, and the number of pieces of inverted data is counted by the pop counter circuit.

7. The semiconductor device according to claim 2,
wherein the memory array circuit includes a plurality of memory blocks including n data lines and a plurality of memory cells connected to the n data lines, and a plurality of block input circuits corresponding to the plurality of memory blocks,
wherein the block input circuit includes n storage circuits and n logic circuits connected to the n data lines and the n storage circuits,
wherein the counter circuit includes
a pop counter circuit that is supplied with n pieces of data to be stored in the n storage circuits in the block input circuit and counts the number of pieces of inverted data in the n pieces of data,
a clock counter circuit that, when the pop counter circuit determines that the number of pieces of inverted data exceeds the predetermined number, counts the number of pieces of inverted data in the n pieces of data and obtains a point at which the number of pieces of inverted data exceeds the predetermined number, and
a calculation circuit that adds a count value of the pop counter circuit and a count value of the clock counter circuit and calculates a separation point indicating a boundary between a plurality of the regions in the plurality of storage circuits that store the data string,
wherein the memory controller sequentially outputs separation point information indicating the separation point calculated by the counter circuit, and
wherein the logic circuit includes a comparator that compares specification information for specifying a region in which a connected storage circuit is arranged with the separation point information, and when the comparator indicates that the region indicated with the specification information is in the region specified by the separation point information, the logic circuit supplies data stored in the connected storage circuit to the data line.

8. The semiconductor device according to claim 2,
wherein the memory controller selects a first region at a first timing and selects a second region including the first region at a second timing subsequent to the first timing, and
wherein the memory controller gives instruction to write the inverted data stored in a plurality of storage circuits included in the first region to a plurality of memory cells at the first timing, and then gives instruction to write non-inverted data to the storage circuit storing the inverted data in the first region.

9. The semiconductor device according to claim 8,
wherein the memory array circuit includes a plurality of memory blocks including n data lines and a plurality of memory cells connected to the n data lines, and a plurality of block input circuits corresponding to the plurality of memory blocks,
wherein the block input circuit includes n storage circuits corresponding to the n data lines and n logic circuits connected to the n data lines and the n storage circuits, and
wherein the counter circuit includes
a first counter circuit that generates a first block select signal indicating a region in which the number of pieces of inverted data is less than the predetermined number at the first timing, and
a second counter circuit that generates a first data signal indicating a region across the region indicated by the first block select signal until the number of pieces of inverted data reaches the predetermined number at the first timing.

10. The semiconductor device according to claim 9,
wherein the first counter circuit includes a pop counter circuit that is supplied with n pieces of data to be stored in the n storage circuits in the block input circuit and counts the number of pieces of inverted data in the n pieces of data, and
wherein the second counter circuit includes a clock counter circuit that counts the number of pieces of inverted data in a region across the first region.

11. A writing method comprising:
a memory array circuit configured to include a plurality of data lines, a plurality of memory cells connected to the plurality of data lines, and an input circuit that includes a plurality of storage circuits, is supplied with a high voltage during writing, and writes data to the memory cells according to data held in the storage circuits; and
a memory controller configured to supply a data string having a number of pieces of data corresponding to a number of the storage circuits to the input circuit and cause the plurality of storage circuits to hold the data string,
wherein inverted data that changes a state of the memory cell by writing to the memory cell and non-inverted data that does not change the state of the memory cell are mixed in the data string, and
wherein the memory controller counts a number of pieces of the inverted data included in the data string during a period in which the high voltage is generated, and
divides the plurality of storage circuits into a plurality of regions so that the number of storage circuits that store the inverted data is equal to or less than a predetermined number in the count, selects the plurality of regions at different timings, and writes data held in the storage circuits arranged in the selected regions to the memory cell.
